(19) United States
(12) Patent Application Publication
(10) Pub. No.: US 2026/0337767 A1
(43) Pub. Date: Oct. 29, 2026

(54) PROCESSES FOR PREPARING COATED POWDER COMPOSITIONS

(71) Applicant: Applied Materials, Inc., Santa Clara, CA (US)

(72) Inventors: Ravindra PATIL, Santa Clara, CA (US); David Masayuki ISHIKAWA, Mountain View, CA (US); Yuriy MELNIK, San Jose, CA (US); Miaojun WANG, Santa Clara, CA (US); Brian Hayes BURROWS, San Jose, CA (US); Shrikant SWAMINATHAN, Bangalore (IN); Neha GUPTA, Bangalore (IN); Vikas Vijay GUJAR, Bangalore (IN)

(21) Appl. No.: 19/120,516

(22) PCT Filed: Oct. 27, 2023
(86) PCT No.: PCT/US2023/036104

§ 371 Date: Apr. 11, 2025

Related U.S. Application Data
(60) Provisional application No. 63/420,291, filed on Oct. 28, 2022.

(51) Int. Cl. C23C 16/44; C23C 16/455

(52) U.S. Cl. CPC C23C 16/4417; C23C 16/4408; C23C 16/45527; C23C 16/45553

(57) ABSTRACT

Embodiments of the present disclosure generally relate to vapor coating processes for preparing coated powder compositions. In one or more embodiments, a method to prepare a coated powder composition is provided and includes positioning a plurality of powder particles within a processing region, where each of the powder particles contains one or more organic materials, one or more inorganic materials, or combinations thereof, and coating the plurality of powder particles with a metal oxide coating to form a plurality of coated particles during a cyclic vapor coating process. The metal oxide coating contains aluminum oxide, zinc oxide, or aluminum zinc oxide, and the cyclic vapor coating process includes one or more deposition cycles.

### BACKGROUND

### Field

Embodiments of the present disclosure generally relate to coating processes, and more specifically, vapor coating processes for preparing coated particles.

### Description of the Related Art

Atomic layer epitaxy (ALE) and atomic layer deposition (ALD) are a self-limiting processes, each utilize alternated pulses of reactants to saturate a substrate surface and leave a monolayer of material per cycle. Each of the reactant pulses typically lasts in a range from a few milliseconds to several seconds. The deposition conditions and reactants are selected to ensure self-saturating reactions, such that an adsorbed layer in one pulse leaves a surface termination that is non-reactive with the gas phase reactants of the same pulse. A subsequent pulse of a different reactant reacts with the previous termination to enable continued deposition. Thus, each cycle of alternated pulses typically leaves about one molecular layer of the deposited material.

Materials produced by ALE or ALD processes are typically deposited on substrates, such as semi-conductor or microelectronic substrates, which usually have relatively large flat wafer surfaces, such as a silicon wafer with a 200 mm or 300 mm diameter. These ALE and ALD processes are often conducted as a thermal reaction or a plasma reaction and at temperatures of greater than 50 °C, such as 100 °C to 500 °C or even great temperatures. Also, particles of organic materials often decompose if heated to temperatures generally used during an ALE or ALD process.

Therefore, a need exists for improved processes for preparing coated particles.

### SUMMARY

Embodiments of the present disclosure generally relate to vapor coating processes for preparing coated powder compositions. The coated powder composition is prepared from powder particles can be or contain one or more organic materials (e.g., active pharmaceutical ingredients (APIs), pharmaceutically acceptable excipients (PAEs), and/or other organic compounds), one or more inorganic materials (e.g., metal oxide particles), or combinations thereof. The plurality of powder particles are coated with a metal oxide, such as aluminum oxide, zinc oxide, or aluminum zinc oxide.

In one or more embodiments, a method of forming, producing, or otherwise preparing a coated powder composition is provided and includes positioning a plurality of powder particles within a processing region of a processing chamber, wherein each of the powder particles can be or contain an organic material, and coating the plurality of powder particles with a metal oxide coating to form a plurality of coated particles during a cyclic vapor coating process. The metal oxide coating contains aluminum oxide, zinc oxide, or aluminum zinc oxide. The cyclic vapor coating process includes one or more deposition cycles. Each of the deposition cycles includes introducing two or more pulses of a metal precursor into the processing region via a first mass flow control (MFC) valve, exposing the plurality of powder particles to the metal precursor, and infiltrating the plurality of powder particles with the metal precursor via spaces between the powder particles. Thereafter, each of the deposition cycles includes introducing two or more pulses of a purge gas into the processing region via a second MFC valve, and exposing the plurality of powder particles to the purge gas during a first purge process. Thereafter, each of the deposition cycles includes introducing two or more pulses of an oxidizing agent into the processing region via a third MFC valve, exposing the plurality of powder particles to the oxidizing agent, and infiltrating the plurality of powder particles with the oxidizing agent via spaces between the powder particles to produce the metal oxide coating disposed on outer surfaces of each of the powder particles. Thereafter, each of the deposition cycles includes introducing two or more pulses of the purge gas via the second MFC valve, and exposing the plurality of powder particles to the purge gas during a second purge process.

In some embodiments, a method of forming, producing, or otherwise preparing a coated powder composition is provided and includes positioning a plurality of powder particles within a processing region of a processing chamber, wherein each of the powder particles can be or contain an inorganic material, and coating the plurality of powder particles with a metal oxide coating to form a plurality of coated particles during a cyclic vapor coating process. The metal oxide coating contains aluminum oxide, zinc oxide, or aluminum zinc oxide. The cyclic vapor coating process includes one or more deposition cycles. Each of the deposition cycles includes introducing two or more pulses of a metal precursor into the processing region via a first MFC valve, exposing the plurality of powder particles to the metal precursor, and infiltrating the plurality of powder particles with the metal precursor via spaces between the powder particles. Thereafter, each of the deposition cycles includes introducing two or more pulses of a purge gas into the processing region via a second MFC valve, and exposing the plurality of powder particles to the purge gas during a first purge process. Thereafter, each of the deposition cycles includes introducing two or more pulses of an oxidizing agent into the processing region via a third MFC valve, exposing the plurality of powder particles to the oxidizing agent, and infiltrating the plurality of powder particles with the oxidizing agent via spaces between the powder particles to produce the metal oxide coating disposed on outer surfaces of each of the powder particles. Thereafter, each of the deposition cycles includes introducing two or more pulses of the purge gas via the second MFC valve, and exposing the plurality of powder particles to the purge gas during a second purge process.

In other embodiments, a method of forming, producing, or otherwise preparing a coated powder composition is provided and includes positioning a plurality of powder particles within a processing region of a processing chamber, and coating the plurality of powder particles with a metal oxide coating to form a plurality of coated particles during a cyclic vapor coating process. The metal oxide coating contains aluminum zinc oxide. The cyclic vapor coating process includes one or more deposition cycles, and each of the deposition cycles includes introducing two or more pulses of a first metal precursor into the processing region via a first MFC valve, exposing the plurality of powder particles to the first metal precursor, and infiltrating the plurality of powder particles with the first metal precursor via spaces between the powder particles. Thereafter, each of the deposition cycles includes introducing two or more pulses of a purge gas into the processing region via a second MFC valve, and exposing the plurality of powder particles to the purge gas during a first purge process. Thereafter, each of the deposition cycles includes introducing two or more pulses of an oxidizing agent into the processing region via a third MFC valve, exposing the plurality of powder particles to the oxidizing agent, and infiltrating the plurality of powder particles with the oxidizing agent via spaces between the powder particles to produce a first metal oxide layer disposed on outer surfaces of each of the powder particles. Thereafter, each of the deposition cycles includes introducing two or more pulses of the purge gas via the second MFC valve, and exposing the plurality of powder particles to the purge gas during a second purge process. Thereafter, each of the deposition cycles includes introducing two or more pulses of a second metal precursor into the processing region via a fourth MFC valve, exposing the plurality of powder particles to the second metal precursor, and infiltrating the plurality of powder particles with the second metal precursor via spaces between the powder particles. Thereafter, each of the deposition cycles includes introducing two or more pulses of the purge gas into the processing region via the second MFC valve, and exposing the plurality of powder particles to the purge gas during a third purge process. Thereafter, each of the deposition cycles includes introducing two or more pulses of the oxidizing agent into the processing region via the third MFC valve, exposing the plurality of powder particles to the oxidizing agent, and infiltrating the plurality of powder particles with the oxidizing agent via spaces between the powder particles to produce a second metal oxide layer disposed on the first metal oxide layer disposed on the outer surfaces of each of the powder particles. Thereafter, each of the deposition cycles includes introducing two or more pulses of the purge gas via the second MFC valve, and exposing the plurality of powder particles to the purge gas during a fourth purge process. The first and second metal precursors are different from each other. The metal oxide coating contains the first metal oxide layer and the second metal oxide layer. The first metal oxide layer contains aluminum oxide, then the second metal oxide layer contains zinc oxide, or alternatively, the first metal oxide layer contains zinc oxide, then the second metal oxide layer contains aluminum oxide.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1B are flow charts depicting one or more cyclic vapor coating processes, as described and discussed in one or more embodiments herein.

FIGS. 2A-2B are flow charts depicting other cyclic vapor coating processes, as described and discussed in one or more embodiments herein.

FIGS. 3A-3C depict a deposition system which can be used to perform cyclic vapor coating processes, as described and discussed in one or more embodiments herein. FIG. 3A depicts a schematic cross-sectional front view of the deposition system, FIG. 3B depicts a schematic side view of the deposition system shown in FIG. 3A, and FIG. 3C is a schematic cross-sectional side view of the deposition system shown in FIG. 3A. The view of FIG. 3C can be taken along line 3C-3C in FIG. 3A.

To facilitate understanding, identical reference numerals have been used, where possible, to designate identical elements that are common to the Figures. It is contemplated that elements and features of one or more embodiments may be beneficially incorporated in other embodiments.

### DETAILED DESCRIPTION

Embodiments of the present disclosure generally relate to vapor coating processes for preparing coated powder compositions. The coated powder composition is prepared from powder particles can be or contain one or more organic materials (e.g., active pharmaceutical ingredients (APIs), pharmaceutically acceptable excipients (PAEs), and/or other organic compounds), one or more inorganic materials (e.g., metal oxide particles), or combinations thereof. The plurality of powder particles are coated with a metal oxide, such as aluminum oxide, zinc oxide, or aluminum zinc oxide.

In one or more embodiments, a method of forming, producing, or otherwise preparing a coated powder composition is provided and includes positioning a plurality of powder particles within a processing region of a processing chamber or reactor and coating the plurality of powder particles with a metal oxide coating to form a plurality of coated particles during a cyclic vapor coating process. Each of the powder particles can be or contain one or more organic materials, one or more inorganic materials, or any combination thereof. The metal oxide coating contains aluminum oxide, zinc oxide, or aluminum zinc oxide.

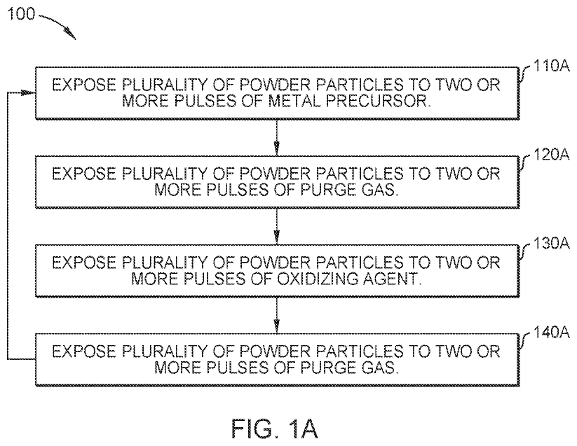

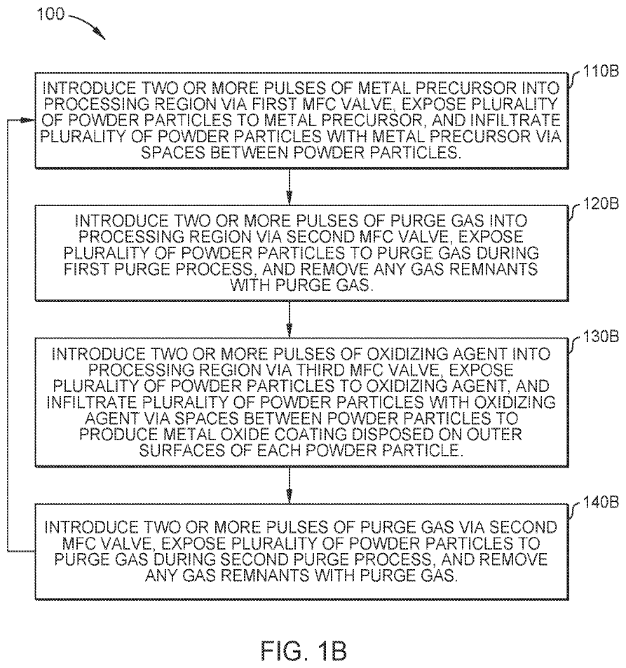

FIGS. 1A-1B are flow charts depicting a cyclic vapor coating process 100, as described and discussed in one or more embodiments herein. In some embodiments, each of the deposition cycles of the cyclic vapor coating process 100 includes operations 110a-140a, as depicted in FIG. 1A. In other embodiments, each of the deposition cycles of the cyclic vapor coating process 100 includes operations 110b-140b, as depicted in FIG. 1B. The cyclic vapor coating process 100 may include one, two, three, or more deposition cycles. Each of the deposition cycles of the cyclic vapor coating process 100 can be repeated to form, produce, or otherwise prepare the metal oxide coating having a desired thickness. A metal oxide coating containing aluminum oxide or zinc oxide can be prepared by the cyclic vapor coating process 100.

In one or more embodiments, as shown in FIG. 1A, the plurality of powder particles is exposed to two or more pulses of the metal precursor (in operation 110a), then the plurality of powder particles is exposed to two or more pulses of the purge gas (in operation 120a), then the plurality of powder particles is exposed to two or more pulses of the oxidizing agent (in operation 130a), and then the plurality of powder particles is exposed to two or more pulses of the purge gas (in operation 140a) during the cyclic vapor coating process 100.

In other embodiments, as shown in FIG. 1B, in operation 110b, during a metal precursor exposure process, two or more pulses of a metal precursor are introduced into the processing region of the processing chamber or reactor via a first mass flow control (MFC) valve. The plurality of powder particles are exposed to the metal precursor. The plurality of powder particles is infiltrated by the metal precursor via spaces disposed between the powder particles.

In operation 120b, during a first purge process, two or more pulses of a purge gas are introduced into the processing region via a second MFC valve. The plurality of powder particles is exposed to the purge gas. The plurality of powder particles is infiltrated by the purge gas via spaces between the powder particles, and any gas remnants is removed by purge gas. The gas remnants may contain excess amounts of the metal precursor, the purge gas, and/or other gases within the processing region.

In operation 130b, during an oxidizing agent exposure process, two or more pulses of an oxidizing agent are introduced into the processing region via a third MFC valve. The plurality of powder particles is exposed to the oxidizing agent. The plurality of powder particles are infiltrated by the oxidizing agent via spaces between the powder particles to produce the metal oxide coating disposed on outer surfaces of each of the powder particles.

In operation 140b, during a second purge process, two or more pulses of the purge gas are introduced into the processing region via a second MFC valve. The plurality of powder particles is exposed to the purge gas. The plurality of powder particles is infiltrated by the purge gas via spaces between the powder particles, and any gas remnants is removed by purge gas. The gas remnants may contain excess amounts of the metal precursor, the oxidizing agent, the purge gas, one or more reaction by-products, and/or other gases within the processing region.

In some examples while conducting the cyclic vapor coating process 100, the metal precursor contains an aluminum precursor and the metal oxide coating contains aluminum oxide. In other examples while conducting the cyclic vapor coating process 100, the metal precursor contains a zinc precursor and the metal oxide coating contains zinc oxide.

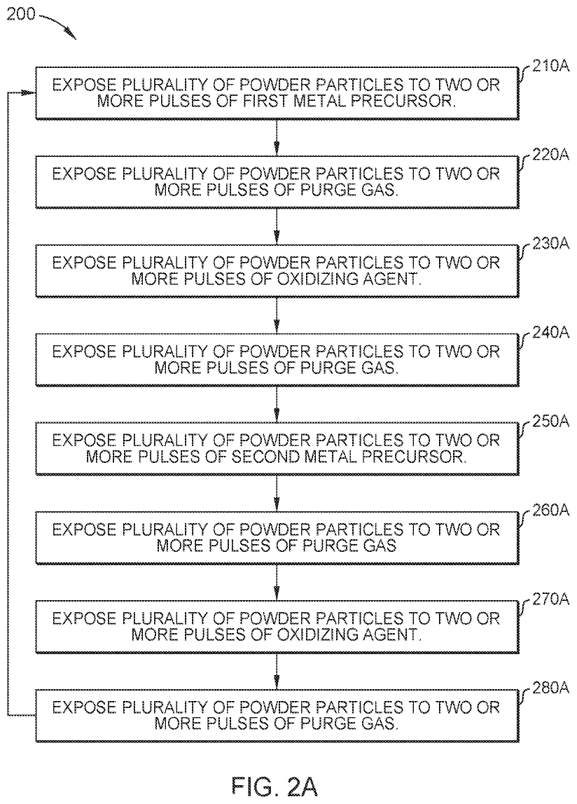

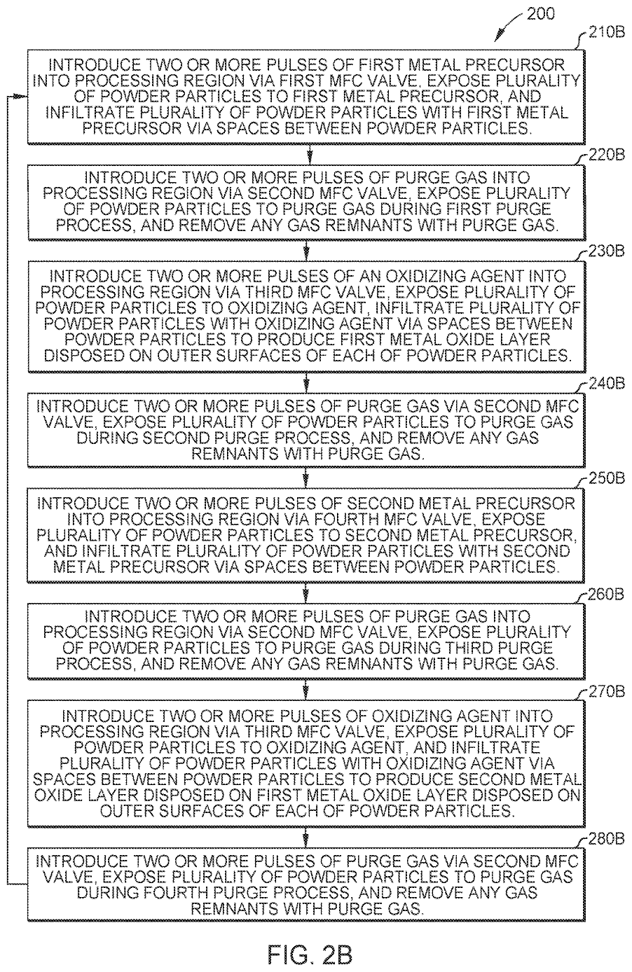

FIGS. 2A-2B are flow charts depicting a cyclic vapor coating process 200, as described and discussed in one or more embodiments herein. In some embodiments, each of the deposition cycles of the cyclic vapor coating process 200 includes operations 210a-280a, as depicted in FIG. 2A. In other embodiments, each of the deposition cycles of the cyclic vapor coating process 200 includes operations 210b-280b, as depicted in FIG. 2B. The cyclic vapor coating process 200 may include one, two, three, or more deposition cycles. Each of the deposition cycles of the cyclic vapor coating process 200 can be repeated to form, produce, or otherwise prepare the metal oxide coating having a desired thickness. A metal oxide coating containing aluminum zinc oxide can be prepared by the cyclic vapor coating process 200. The metal oxide coating contains at least one layer of aluminum oxide and at least one layer of zinc oxide forming the aluminum zinc oxide. The metal oxide coating contains sequential pairs of aluminum oxide layers and zinc oxide layers.

In one or more embodiments, as shown in FIG. 2A, the plurality of powder particles is exposed to two or more pulses of the first metal precursor (in operation 210a), then the plurality of powder particles is exposed to two or more pulses of the purge gas (in operation 220a), then the plurality of powder particles is exposed to two or more pulses of the oxidizing agent (in operation 230a), and then the plurality of powder particles is exposed to two or more pulses of the purge gas (in operation 240a) during the cyclic vapor coating process 200. Thereafter, the plurality of powder particles is exposed to two or more pulses of the second metal precursor (in operation 250a), then the plurality of powder particles is exposed to two or more pulses of the purge gas (in operation 260a), then the plurality of powder particles is exposed to two or more pulses of the oxidizing agent (in operation 270a), and then the plurality of powder particles is exposed to two or more pulses of the purge gas (in operation 280a) during the cyclic vapor coating process 200.

In other embodiments, as shown in FIG. 2B, in operation 210b, during a first metal precursor exposure process, two or more pulses of a first metal precursor are introduced into the processing region of the processing chamber or reactor via a first MFC valve. The plurality of powder particles are exposed to the first metal precursor. The plurality of powder particles is infiltrated by the first metal precursor via spaces disposed between the powder particles. In some examples, if the first metal precursor is or contains an aluminum precursor at operation 210b, then the second metal precursor is or contains a zinc precursor at operation 250b. In other examples, if the first metal precursor is or contains a zinc precursor at operation 210b, then the second metal precursor is or contains an aluminum precursor at operation 250b.

In operation 220b, during a first purge process, two or more pulses of a purge gas are introduced into the processing region via a second MFC valve. The plurality of powder particles is exposed to the purge gas. The plurality of powder particles is infiltrated by the purge gas via spaces between the powder particles, and any gas remnants is removed by purge gas. The gas remnants may contain excess amounts of the first metal precursor, the purge gas, and/or other gases within the processing region.

In operation 230b, during a first oxidizing agent exposure process, two or more pulses of an oxidizing agent are introduced into the processing region via a third MFC valve. The plurality of powder particles is exposed to the oxidizing agent. The plurality of powder particles are infiltrated by the oxidizing agent via spaces between the powder particles to produce the first metal oxide layer disposed on outer surfaces of each of the powder particles. The first metal oxide layer is a portion of the metal oxide coating to be prepared by the cyclic vapor coating process 200.

In operation 240b, during a second purge process, two or more pulses of the purge gas are introduced into the processing region via the second MFC valve. The plurality of powder particles is exposed to the purge gas. The plurality of powder particles is infiltrated by the purge gas via spaces between the powder particles, and any gas remnants is removed by purge gas. The gas remnants may contain excess amounts of the first metal precursor, the oxidizing agent, the purge gas, one or more reaction by-products, and/or other gases within the processing region.

In operation 250b, during a second metal precursor exposure process, two or more pulses of a second metal precursor are introduced into the processing region of the processing chamber or reactor via a fourth MFC valve. The plurality of powder particles are exposed to the second metal precursor. The plurality of powder particles is infiltrated by the second metal precursor via spaces disposed between the powder particles.

In operation 260b, during a third purge process, two or more pulses of the purge gas are introduced into the processing region via the second MFC valve. The plurality of powder particles is exposed to the purge gas. The plurality of powder particles is infiltrated by the purge gas via spaces between the powder particles, and any gas remnants is removed by purge gas. The gas remnants may contain excess amounts of the first metal precursor, the second metal precursor, the oxidizing agent, the purge gas, one or more reaction by-products, and/or other gases within the processing region.

In operation 270b, during a second oxidizing agent exposure process, two or more pulses of the oxidizing agent are introduced into the processing region via the third MFC valve. The plurality of powder particles is exposed to the oxidizing agent. The plurality of powder particles are infiltrated by the oxidizing agent via spaces between the powder particles to produce the second metal oxide layer disposed on the first metal oxide layer disposed on outer surfaces of each of the powder particles. The first and second metal oxide layers form the metal oxide coating prepared by the cyclic vapor coating process 200.

In operation 280b, during a fourth purge process, two or more pulses of the purge gas are introduced into the processing region via the second MFC valve. The plurality of powder particles is exposed to the purge gas. The plurality of powder particles is infiltrated by the purge gas via spaces between the powder particles, and any gas remnants is removed by purge gas. The gas remnants may contain excess amounts of the first metal precursor, the second metal precursor, the oxidizing agent, the purge gas, one or more reaction by-products, and/or other gases within the processing region.

For preparing the metal oxide coating containing aluminum zinc oxide by the cyclic vapor coating process 200, the first and second metal precursors are different from each other, such as an aluminum precursor and a zinc precursor. In some examples while conducting the cyclic vapor coating process 200, the first metal precursor is or contains an aluminum precursor and the first metal oxide layer contains aluminum oxide, while the second metal precursor is or contains a zinc precursor and the second metal oxide layer contains zinc oxide. In other examples while conducting the cyclic vapor coating process 200, the first metal precursor is or contains a zinc precursor and the first metal oxide layer contains zinc oxide, while the second metal precursor is or contains an aluminum precursor and the second metal oxide layer contains aluminum oxide.

### Powder Particles

The powder particles, coated by the cyclic vapor coating processes 100, 200 to produce coated particles, can be or contain one or more organic materials, one or more inorganic materials, or any combination thereof. In one or more embodiments, the powder particles contain one or more organic materials. The organic material contained in the powder particles can be or contain one or more drugs, one or more active pharmaceutical ingredients (APIs), one or more pharmaceutically acceptable excipients (PAEs), other type of organic compounds, or any combination thereof. A “drug” in its broadest sense includes all small molecule (e.g., non-biologic) APIs. Exemplary drugs and/or APIs can be or include an analgesic, an anesthetic, an anti-inflammatory agent, an anthelmintic, an anti-arrhythmic agent, an antiasthma agent, an antibiotic, an anticancer agent, an anticoagulant, an antidepressant, an antidiabetic agent, an antiepileptic, an antihistamine, an antitussive, an antihypertensive agent, an antimuscarinic agent, an antimycobacterial agent, an antineoplastic agent, an antioxidant agent, an antipyretic, an immunosuppressant, an immunostimulant, an antithyroid agent, an antiviral agent, an anxiolytic sedative, a hypnotic, a neuroleptic, an astringent, a bacteriostatic agent, a beta-adrenoceptor blocking agent, a blood product, a blood substitute, a bronchodilator, a buffering agent, a cardiac inotropic agent, a chemotherapeutic, a contrast media, a corticosteroid, a cough suppressant, an expectorant, a mucolytic, a diuretic, a dopaminergic, an antiparkinsonian agent, a free radical scavenging agent, a growth factor, a haemostatic, an immunological agent, a lipid regulating agent, a muscle relaxant, a parasympathomimetic, a parathyroid calcitonin, a biphosphonate, a prostaglandin, a radio-pharmaceutical, a hormone, a sex hormone, an anti-allergic agent, an appetite stimulant, an anoretic, a steroid, a sympathomimetic, a thyroid agent, a vaccine, a vasodilator, a xanthine, salts thereof, complexes thereof, or any combination thereof. Exemplary types of small molecule drugs can be or include acetaminophen, clarithromycin, azithromycin, ibuprofen, fluticasone propionate, salmeterol, pazopanib HCl, palbociclib, and amoxicillin potassium clavulanate, salts thereof, complexes thereof, or any combination thereof.

Exemplary PAEs, diluents, and/or carriers can be or include surfactants, polymers, sugars, binding agents, filling agents, lubricating agents, sweeteners, flavoring agents, preservatives, buffers, diluents, wetting agents, disintegrants, effervescent agents, salts thereof, hydrates thereof, or any combination thereof. Exemplary surfactants and polymers can be or include polyethylene glycol (PEG), polyvinylpyrrolidone (PVP), sodium lauryl sulfate, polyvinylalcohol, crospovidone, polyvinylpyrrolidone-polyvinylacrylate copolymer, cellulose derivatives, hydroxypropylmethyl cellulose, hydroxypropyl cellulose, carboxymethylethyl cellulose, hydroxypropyllmethyl cellulose phthalate, polyacrylates and polymethacrylates, urea, sugars, polyols, carbomer and their polymers, emulsifiers, sugar gum, starch, organic acids and their salts, vinyl pyrrolidone and vinyl acetate, salts thereof, esters thereof, or any combination thereof. Exemplary binding agents can be or include cellulose, cross-linked polyvinylpyrrolidone, microcrystalline cellulose, salts thereof, or any combination thereof. Exemplary filling agents can be or include lactose monohydrate, lactose anhydrous, microcrystalline cellulose, starches, salts thereof, complexes thereof, or any combination thereof. Exemplary lubricating agents such as agents that act on the flowability of a powder to be compressed, can be or include colloidal silicon dioxide, talc, stearic acid, magnesium stearate, calcium stearate, silica gel, or any combination thereof. Exemplary sweeteners can be or include sucrose, xylitol, sodium saccharin, cyclamate, aspartame, and acesulfame K, other natural sweeteners, other artificial sweeteners, salts thereof, or any combination thereof. Exemplary preservatives can be or include potassium sorbate, methylparaben, propylparaben, benzoic acid, benzoates, parahydroxybenzoic acid, esters of parahydroxybenzoic acid (e.g., butylparaben), alcohols (ethyl alcohol or benzyl alcohol), phenolic chemicals (e.g., phenol), quarternary compounds (e.g., benzalkonium chloride), salts thereof, esters thereof, or any combination thereof. Exemplary diluents and/or pharmaceutically acceptable inert fillers can be or include microcrystalline cellulose, lactose, dibasic calcium phosphate, saccharides, salts thereof, or any combination thereof. Exemplary wetting agents can be or include corn starch, potato starch, maize starch, modified starches, salts thereof, or any combination thereof. Exemplary disintegrants can be or include croscarmellose sodium, crospovidone, sodium starch glycolate, salts thereof, or any combination thereof. Exemplary effervescent agents and/or effervescent couples can be or include organic acids (e.g., citric, tartaric, malic, fumaric, adipic, succinic, and alginic acids, anhydrides, and/or acid salts), or a carbonate (e.g., sodium carbonate, potassium carbonate, magnesium carbonate, sodium glycine carbonate, L-lysine carbonate, and arginine carbonate) or bicarbonate (e.g., sodium bicarbonate or potassium bicarbonate), salts thereof, esters thereof, or any combination thereof.

In some embodiments, the powder particles contain one or more inorganic materials. The inorganic material contained in the powder particles can be or contain one or more metal oxides, one or more metal nitrides, silicon oxide, silicon nitride, or any combination thereof. For example, the inorganic material contained in the powder particles can be or contain aluminum oxide, titanium dioxide, iron oxide, gallium oxide, magnesium oxide, zinc oxide, niobium oxide, hafnium oxide, tantalum oxide, lanthanum oxide, zirconium dioxide, silicon oxide, silicates thereof, nitrides thereof, or any combination thereof.

In some examples, the plurality of powder particles is produced from a spray dried process or a lyophilization process, regardless of containing one or more organic materials, one or more inorganic materials, or combinations thereof. Other techniques can be used to make, fabricate, or otherwise produce the plurality of powder particles.

The plurality of powder particles can have an average particle size in a range from about 0.1 μm, about 0.2 μm, about 0.3 μm, about 0.5 μm, about 0.8 μm, about 1 μm, about 2 μm, about 3 μm, about 5 μm, about 8 μm, about 10 μm, about 12 μm, about 15 μm, about 18 μm, about 20 μm, about 25 μm, about 30 μm, or about 35 μm to about 40 μm, about 50 μm, about 60 μm, about 70 μm, about 80 μm, about 90 μm, about 100 μm, about 120 μm, about 150 μm, about 200 μm, about 300 μm, about 400 μm, about 500 μm, about 600 μm, about 700 μm, about 800 μm, about 900 μm, or about 1,000 μm. For example, the plurality of powder particles can have an average particle size of about 0.1 μm to about 1,000 μm, about 0.1 μm to about 500 μm, about 0.1 μm to about 200 μm, about 0.1 μm to about 150 μm, about 0.1 μm to about 100 μm, about 0.1 μm to about 80 μm, about 0.1 μm to about 50 μm, about 0.1 μm to about 30 μm, about 0.1 μm to about 20 μm, about 0.1 μm to about 10 μm, about 0.1 μm to about 8 μm, about 0.1 μm to about 5 μm, about 0.1 μm to about 2 μm, about 0.1 μm to about 1 μm, about 0.1 μm to about 0.5 μm, about 1 μm to about 1,000 μm, about 1 μm to about 500 μm, about 1 μm to about 200 μm, about 1 μm to about 150 μm, about 1 μm to about 100 μm, about 1 μm to about 80 μm, about 1 μm to about 50 μm, about 1 μm to about 30 μm, about 1 μm to about 20 μm, about 1 μm to about 10 μm, about 1 μm to about 8 μm, about 1 μm to about 5 μm, about 1 μm to about 2 μm, about 10 μm to about 1,000 μm, about 10 μm to about 500 μm, about 10 μm to about 200 μm, about 10 μm to about 150 μm, about 10 μm to about 100 μm, about 10 μm to about 80 μm, about 10 μm to about 50 μm, about 10 μm to about 30 μm, about 10 μm to about 20 μm, or about 10 μm to about 15 μm.

In one or more examples, the plurality of powder particles can have an average particle size of about 0.1 μm to about 1,000 μm. In some examples, the plurality of powder particles can have an average particle size of about 1 μm to about 100 μm. In other examples, the plurality of powder particles can have an average particle size of about 1 μm to about 30 μm, or about 1 μm to about 10 μm.

### Cyclic Vapor Coating Process

In embodiments described and discussed herein, a plurality of powder particles can be coated by the cyclic vapor coating processes 100, 200 to form, produce, or otherwise prepare the coated powder composition. The cyclic vapor coating processes 100, 200 are stagnant flow vapor deposition processes which provide consistent and uniform metal oxide coatings on the powder particles. The method includes a mass flow controller (“MFC”) calibrated to deliver a precise number of chemical moles to a pressure isolated vessel. Any of the MFCs can have an orifice sized (e.g., about 0.062 inches or greater) for delivery of the metal precursor (e.g., metal organic vapor) at room temperature (e.g., about 25 °C or less) and thus at low vapor pressure (e.g., about 20 Torr or less). The orifices of the MFCs used for the oxidizing agent and the purge gas may also be sized at about 0.062 inches or greater.

Some active pharmaceutical ingredients (“API's”) are prone to thermal decomposition and some high surface area substrates (e.g., powder particles) are prone to non-uniform coating during conventional deposition processes. However, the cyclic vapor coating processes 100, 200 with the stagnant flow and utilizing the MFCs described and discussed herein overcome these shortcomings and include metal organic vapor delivery at near room temperature by compensating for ampoule pressure drift and for increasing chamber pressure due to reaction byproduct evolution. Some embodiments enable dosing control and provide process verification for Good Manufacturing Practice (“GMP”) compliance.

Several different types of chambers or reactors can be used to perform the cyclic vapor coating processes 100, 200. The chambers and/or reactors contains a processing region to contain the plurality of powder particles which is coated by the cyclic vapor coating process to form, produce, or otherwise prepare the coated powder composition. In some embodiments, rotary reactors with drums, stationary reactors with paddles, and other types of chambers and reactors can be used to perform the cyclic vapor coating processes 100, 200 and are further disclosed in U.S. Pat. No. 11,674,223B2, and U.S. Pub. No. 20230128094A1, which are incorporated by reference in their entirety. Other traditional chemical vapor deposition (CVD) chambers reactors or atomic layer deposition (ALD) chambers or reactors can be used as the processing chamber suitable for performing the cyclic vapor coating processes or the vapor deposition processes 100, 200. An example of a tool or system that benefit from the cyclic vapor coating process is the Centura® system or Endura® system with an iSprint™ ALD/CVD SSW chamber, commercially available from Applied Materials, Inc.

In one or more embodiments, the plurality of powder particles can be heated, cooled, or otherwise maintained at a temperature in a range from about 0 °C, about 10 °C, about 12 °C, about 15 °C, about 18 °C or about 20 °C to about 22 °C, about 23 °C, about 25 °C, about 28 °C, or about 30 °C during the cyclic vapor coating processes 100, 200. For example, the plurality of powder particles can be heated, cooled, or otherwise maintained at a temperature of about 0 °C to about 30 °C, about 0 °C to about 25 °C, about 10 °C to about 25 °C, about 15 °C to about 25 °C, about 18 °C to about 25 °C, about 20 °C to about 25 °C, about 22 °C to about 25 °C, about 0 °C to about 20 °C, about 10 °C to about 20 °C, about 15 °C to about 20 °C, or about 18 °C to about 20 °C during the cyclic vapor coating processes 100, 200.

The processing region within the chamber or reactor can be adjusted or otherwise maintained a stagnate atmosphere at a pressure of less than 760 Torr when each pulse of the metal precursors (e.g., the first metal precursor or the second metal precursor), the oxidizing agent, and/or the purge gas is independently introduced into the processing region during the cyclic vapor coating processes 100, 200. The stagnate atmosphere of the processing region can be at a pressure from about 10 Torr, about 50 Torr, or about 100 Torr to about 200 Torr, about 500 Torr, or about 750 Torr. In one or more examples, the stagnate atmosphere of the processing region can be at a pressure from about 10 Torr to about 750 Torr.

In some examples, the metal precursor (or the first metal precursor or the second metal precursor) can be or contain one or more aluminum precursors used during the cyclic vapor coating processes 100, 200. Exemplary aluminum precursors can be or contain trimethyl aluminum, dimethyl aluminum hydride, triethyl aluminum, diethyl aluminum hydride, tripropyl aluminum, dipropyl aluminum hydride, tributyl aluminum, dibutyl aluminum hydride, isomers thereof, salts thereof, of any combination thereof. In some examples, each pulse of the aluminum precursor is introduced into the processing region without a carrier gas. In other examples, a carrier gas can accompany the aluminum precursor into the processing region. The aluminum precursor (or the first metal precursor or the second metal precursor) can be introduced into the processing region at a flow rate in a range from about 10 sccm, about 20 sccm, about 25 sccm, or about 30 sccm to about 40 sccm, about 50 sccm, about 80 sccm, or about 100 sccm. In one or more examples, the aluminum precursor (or the first metal precursor or the second metal precursor) can be introduced into the processing region at a partial pressure of less than 2 Torr, such as in a range from about 0.001 Torr, about 0.01 Torr, about 0.1 Torr, or about 0.5 Torr to about 0.8 Torr, about 1 Torr, or about 1.8 Torr. In one or more examples, the aluminum precursor (or the first metal precursor or the second metal precursor) can be at a temperature of about −20 °C to about 25 °C, about −20 °C to about 23 °C, about −20 °C to about 20 °C, about −20 °C to about 18 °C, about 0 °C to about 25 °C, about 0 °C to about 23 °C, about 0 °C to about 20 °C, about 0 °C to about 18 °C, about 15 °C to about 25 °C, about 15 °C to about 23 °C, about 15 °C to about 20 °C, or about 15 °C to about 18 °C and at a pressure of about 0.01 Torr to about 20 Torr when being introduced into the MFC valve.

In other examples, the metal precursor (including the first metal precursor or the second metal precursor) can be or contain one or more zinc precursors during the cyclic vapor coating processes 100, 200. Exemplary zinc precursors can be or contain dimethyl zinc, diethyl zinc, dipropyl zinc, dibutyl zinc, isomers thereof, salts thereof, of any combination thereof. In some examples, each pulse of the zinc precursor is introduced into the processing region without a carrier gas. In other examples, a carrier gas can accompany the zinc precursor into the processing region. The zinc precursor (or the first metal precursor or the second metal precursor) can be introduced into the processing region at a flow rate in a range from about 10 sccm, about 20 sccm, about 25 sccm, or about 30 sccm to about 40 sccm, about 50 sccm, about 80 sccm, or about 100 sccm. In one or more examples, the zinc precursor (or the first metal precursor or the second metal precursor) can be introduced into the processing region at a partial pressure of less than 2 Torr, such as in a range from about 0.001 Torr, about 0.01 Torr, about 0.1 Torr, or about 0.5 Torr to about 0.8 Torr, about 1 Torr, or about 1.8 Torr. In one or more examples, the zinc precursor (or the first metal precursor or the second metal precursor) can be at a temperature of about −20 °C to about 25 °C, about −20 °C to about 23 °C, about- 20 °C to about 20 °C, about −20 °C to about 18 °C, about 0 °C to about 25 °C, about 0 °C to about 23 °C, about 0 °C to about 20 °C, about 0 °C to about 18 °C, about 15 °C to about 25 °C, about 15 °C to about 23 °C, about 15 °C to about 20 °C, or about 15 °C to about 18 °C and at a pressure of about 0.01 Torr to about 20 Torr when being introduced into the MFC valve.

The oxidizing agent can be or contain water, oxygen (O₂), hydrogen peroxide, inorganic peroxide, ozone, atomic oxygen, oxygen plasma, or any combination thereof during the cyclic vapor coating processes 100, 200. In some examples, each pulse of the oxidizing agent is introduced into the processing region without a carrier gas. In other examples, a carrier gas can accompany the oxidizing agent into the processing region. The oxidizing agent (e.g., water vapor) can be introduced into the processing region at a flow rate in a range from about 10 sccm, about 20 sccm, about 25 sccm, or about 50 sccm to about 80 sccm, about 100 sccm, about 150 sccm, or about 200 sccm. In one or more examples, the oxidizing agent can be introduced into the processing region at a partial pressure of less than 2 Torr, such as in a range from about 0.001 Torr, about 0.01 Torr, about 0.1 Torr, or about 0.5 Torr to about 0.8 Torr, about 1 Torr, or about 1.8 Torr.

The purge gas (including the first, second, third, and/or fourth purge gases) can be or contain argon, helium, nitrogen (N₂), or any combination thereof during the cyclic vapor coating processes 100, 200. The purge gas can be introduced into the processing region at a flow rate in a range from about 10 sccm, about 20 sccm, about 50 sccm, or about 80 sccm to about 100 sccm, about 200 sccm, about 300 sccm, or about 500 sccm.

In one or more embodiments, each of the deposition cycles of during the cyclic vapor coating processes 100, 200 includes introducing a number of pulses of the metal precursor into the processing region during a metal precursor exposure process. The metal precursor can be the first metal precursor, the second metal precursor, the aluminum precursor, and/or the zinc precursor during the metal precursor exposure process. As such, each of the deposition cycles includes introducing a number of pulses of the metal precursor in a range from 2, 3, 4, 5, 6, 7, 8, 9, 10, about 12, about 15, about 18, about 20, about 25, about 30 pulses to about 32, about 35, about 38, about 40, about 45, about 50, about 60, about 70, about 80, about 90, about 100, about 110, about 120 pulses, or more of the metal precursor into the processing region during the metal precursor exposure process. For example, each of the deposition cycles includes introducing from 2 pulses to about 100 pulses, from 2 pulses to about 80 pulses, from 2 pulses to about 50 pulses, from 2 pulses to about 35 pulses, from 2 pulses to about 30 pulses, from 2 pulses to about 25 pulses, from 2 pulses to about 20 pulses, from 2 pulses to about 15 pulses, from 2 pulses to about 10 pulses, from 2 pulses to about 8 pulses, from 2 pulses to about 5 pulses, from 3 pulses to about 100 pulses, from 3 pulses to about 80 pulses, from 3 pulses to about 50 pulses, from 3 pulses to about 35 pulses, from 3 pulses to about 30 pulses, from 3 pulses to about 25 pulses, from 3 pulses to about 20 pulses, from 3 pulses to about 15 pulses, from 3 pulses to about 10 pulses, from 3 pulses to about 8 pulses, from 3 pulses to about 5 pulses, from 5 pulses to about 100 pulses, from 5 pulses to about 80 pulses, from 5 pulses to about 50 pulses, from 5 pulses to about 35 pulses, from 5 pulses to about 30 pulses, from 5 pulses to about 25 pulses, from 5 pulses to about 20 pulses, from 5 pulses to about 15 pulses, from 5 pulses to about 10 pulses, from 5 pulses to about 8 pulses, from 8 pulses to about 100 pulses, from 8 pulses to about 80 pulses, from 8 pulses to about 50 pulses, from 8 pulses to about 35 pulses, from 8 pulses to about 30 pulses, from 8 pulses to about 25 pulses, from 8 pulses to about 20 pulses, from 8 pulses to about 15 pulses, or from 8 pulses to about 10 pulses of each of the first metal precursor and/or the second metal precursor into the processing region during the metal precursor exposure process.

In one or more examples, each of the deposition cycles includes introducing from 3 pulses of the metal precursor to about 100 pulses of each of the first metal precursor and/or the second metal precursor into the processing region during the metal precursor exposure process. In other examples, each of the deposition cycles includes introducing from 5 pulses of the metal precursor to about 50 pulses of each of the first metal precursor and/or the second metal precursor into the processing region during the metal precursor exposure process. In some examples, each of the deposition cycles includes introducing from 8 pulses of the metal precursor to about 25 pulses of each of the first metal precursor and/or the second metal precursor into the processing region during the metal precursor exposure process.

In some embodiments, each of the pulses of the metal precursor is introduced into the processing region for a period in a range from about 20 seconds, about 30 seconds, about 40 seconds, about 45 seconds, or about 50 seconds to about 60 seconds, about 70 seconds, about 75 seconds, about 80 seconds, about 90 seconds, about 100 seconds, about 120 seconds, or longer during the metal precursor exposure process. For example, the each of the pulses of the metal precursor is introduced into the processing region for about 20 seconds to about 120 seconds, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 30 seconds to about 120 seconds, about 30 seconds to about 100 seconds, about 30 seconds to about 90 seconds, about 30 seconds to about 75 seconds, about 30 seconds to about 60 seconds, about 30 seconds to about 45 seconds, about 40 seconds to about 120 seconds, about 40 seconds to about 100 seconds, about 40 seconds to about 90 seconds, about 40 seconds to about 75 seconds, about 40 seconds to about 60 seconds, about 60 seconds to about 120 seconds, about 60 seconds to about 100 seconds, about 60 seconds to about 90 seconds, or about 60 seconds to about 75 seconds during the metal precursor exposure process.

In between the pulses of the metal precursor introduced into the processing region is a stagnant period when no metal precursor is introduced into the processing region. The metal precursor can infiltrate the plurality of powder particles and absorb to or react with the surfaces of the particles during the stagnant period. This stagnant period can range from about 20 seconds, about 30 seconds, about 40 seconds, about 45 seconds, or about 50 seconds to about 60 seconds, about 70 seconds, about 75 seconds, about 80 seconds, about 90 seconds, about 100 seconds, about 120 seconds, or longer between the pulses of the metal precursor during the metal precursor exposure process. For example, the stagnant period can last for about 20 seconds to about 120 seconds, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 30 seconds to about 120 seconds, about 30 seconds to about 100 seconds, about 30 seconds to about 90 seconds, about 30 seconds to about 75 seconds, about 30 seconds to about 60 seconds, about 30 seconds to about 45 seconds, about 40 seconds to about 120 seconds, about 40 seconds to about 100 seconds, about 40 seconds to about 90 seconds, about 40 seconds to about 75 seconds, about 40 seconds to about 60 seconds, about 60 seconds to about 120 seconds, about 60 seconds to about 100 seconds, about 60 seconds to about 90 seconds, or about 60 seconds to about 75 seconds.

In one or more embodiments, each of the deposition cycles includes introducing a number of pulses of the oxidizing agent into the processing region during an oxidizing agent exposure process. The oxidizing agent can be the first oxidizing agent and/or the second oxidizing agent during the oxidizing agent exposure process. As such, each of the deposition cycles includes introducing a number of pulses of the oxidizing agent in a range from 2, 3, 4, 5, 6, 7, 8, 9, 10, about 12, about 15, about 18, about 20, about 25, about 30 pulses to about 32, about 35, about 38, about 40, about 45, about 50, about 60, about 70, about 80, about 90, about 100, about 110, about 120 pulses, or more of the oxidizing agent into the processing region during the oxidizing agent exposure process. For example, each of the deposition cycles includes introducing from 2 pulses to about 100 pulses, from 2 pulses to about 80 pulses, from 2 pulses to about 50 pulses, from 2 pulses to about 35 pulses, from 2 pulses to about 30 pulses, from 2 pulses to about 25 pulses, from 2 pulses to about 20 pulses, from 2 pulses to about 15 pulses, from 2 pulses to about 10 pulses, from 2 pulses to about 8 pulses, from 2 pulses to about 5 pulses, from 3 pulses to about 100 pulses, from 3 pulses to about 80 pulses, from 3 pulses to about 50 pulses, from 3 pulses to about 35 pulses, from 3 pulses to about 30 pulses, from 3 pulses to about 25 pulses, from 3 pulses to about 20 pulses, from 3 pulses to about 15 pulses, from 3 pulses to about 10 pulses, from 3 pulses to about 8 pulses, from 3 pulses to about 5 pulses, from 5 pulses to about 100 pulses, from 5 pulses to about 80 pulses, from 5 pulses to about 50 pulses, from 5 pulses to about 35 pulses, from 5 pulses to about 30 pulses, from 5 pulses to about 25 pulses, from 5 pulses to about 20 pulses, from 5 pulses to about 15 pulses, from 5 pulses to about 10 pulses, from 5 pulses to about 8 pulses, from 8 pulses to about 100 pulses, from 8 pulses to about 80 pulses, from 8 pulses to about 50 pulses, from 8 pulses to about 35 pulses, from 8 pulses to about 30 pulses, from 8 pulses to about 25 pulses, from 8 pulses to about 20 pulses, from 8 pulses to about 15 pulses, or from 8 pulses to about 10 pulses of each of the first oxidizing agent and/or the second oxidizing agent into the processing region during the oxidizing agent exposure process.

In one or more examples, each of the deposition cycles includes introducing from 3 pulses of the oxidizing agent to about 100 pulses of each of the first oxidizing agent and/or the second oxidizing agent into the processing region during the oxidizing agent exposure process. In other examples, each of the deposition cycles includes introducing from 5 pulses of the oxidizing agent to about 50 pulses of each of the first oxidizing agent and/or the second oxidizing agent into the processing region during the oxidizing agent exposure process. In some examples, each of the deposition cycles includes introducing from 8 pulses of the oxidizing agent to about 25 pulses of each of the first oxidizing agent and/or the second oxidizing agent into the processing region during the oxidizing agent exposure process.

In some embodiments, each of the pulses of the oxidizing agent is introduced into the processing region for a period in a range from about 20 seconds, about 30 seconds, about 40 seconds, about 45 seconds, or about 50 seconds to about 60 seconds, about 70 seconds, about 75 seconds, about 80 seconds, about 90 seconds, about 100 seconds, about 120 seconds, or longer during the oxidizing agent exposure process. For example, the each of the pulses of the oxidizing agent is introduced into the processing region for about 20 seconds to about 120 seconds, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 30 seconds to about 120 seconds, about 30 seconds to about 100 seconds, about 30 seconds to about 90 seconds, about 30 seconds to about 75 seconds, about 30 seconds to about 60 seconds, about 30 seconds to about 45 seconds, about 40 seconds to about 120 seconds, about 40 seconds to about 100 seconds, about 40 seconds to about 90 seconds, about 40 seconds to about 75 seconds, about 40 seconds to about 60 seconds, about 60 seconds to about 120 seconds, about 60 seconds to about 100 seconds, about 60 seconds to about 90 seconds, or about 60 seconds to about 75 seconds during the oxidizing agent exposure process.

In between the pulses of the oxidizing agent introduced into the processing region is a stagnant period when no oxidizing agent is introduced into the processing region. The oxidizing agent can infiltrate the plurality of powder particles and absorb to or react with the surfaces of the particles during the stagnant period. This stagnant period can range from about 20 seconds, about 30 seconds, about 40 seconds, about 45 seconds, or about 50 seconds to about 60 seconds, about 70 seconds, about 75 seconds, about 80 seconds, about 90 seconds, about 100 seconds, about 120 seconds, or longer during the oxidizing agent exposure process. For example, the stagnant period can last for about 20 seconds to about 120 seconds, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 30 seconds to about 120 seconds, about 30 seconds to about 100 seconds, about 30 seconds to about 90 seconds, about 30 seconds to about 75 seconds, about 30 seconds to about 60 seconds, about 30 seconds to about 45 seconds, about 40 seconds to about 120 seconds, about 40 seconds to about 100 seconds, about 40 seconds to about 90 seconds, about 40 seconds to about 75 seconds, about 40 seconds to about 60 seconds, about 60 seconds to about 120 seconds, about 60 seconds to about 100 seconds, about 60 seconds to about 90 seconds, or about 60 seconds to about 75 seconds.

In one or more embodiments, each of the deposition cycles includes introducing a number of pulses of the purge gas into the processing region, where the purge gas can independently be the first purge gas, the second purge gas, the third purge gas, and/or the fourth purge gas during a purge process. As such, each of the deposition cycles includes introducing a number of pulses of the purge gas in a range from 2, 3, 4, 5, 6, 7, 8, 9, 10, about 12, about 15, about 18, about 20, about 25, about 30 pulses to about 32, about 35, about 38, about 40, about 45, about 50, about 60, about 70, about 80, about 90, about 100, about 110, about 120 pulses, or more of the purge gas into the processing region during the purge process. For example, each of the deposition cycles includes introducing from 2 pulses to about 100 pulses, from 2 pulses to about 80 pulses, from 2 pulses to about 50 pulses, from 2 pulses to about 35 pulses, from 2 pulses to about 30 pulses, from 2 pulses to about 25 pulses, from 2 pulses to about 20 pulses, from 2 pulses to about 15 pulses, from 2 pulses to about 10 pulses, from 2 pulses to about 8 pulses, from 2 pulses to about 5 pulses, from 3 pulses to about 100 pulses, from 3 pulses to about 80 pulses, from 3 pulses to about 50 pulses, from 3 pulses to about 35 pulses, from 3 pulses to about 30 pulses, from 3 pulses to about 25 pulses, from 3 pulses to about 20 pulses, from 3 pulses to about 15 pulses, from 3 pulses to about 10 pulses, from 3 pulses to about 8 pulses, from 3 pulses to about 5 pulses, from 5 pulses to about 100 pulses, from 5 pulses to about 80 pulses, from 5 pulses to about 50 pulses, from 5 pulses to about 35 pulses, from 5 pulses to about 30 pulses, from 5 pulses to about 25 pulses, from 5 pulses to about 20 pulses, from 5 pulses to about 15 pulses, from 5 pulses to about 10 pulses, from 5 pulses to about 8 pulses, from 8 pulses to about 100 pulses, from 8 pulses to about 80 pulses, from 8 pulses to about 50 pulses, from 8 pulses to about 35 pulses, from 8 pulses to about 30 pulses, from 8 pulses to about 25 pulses, from 8 pulses to about 20 pulses, from 8 pulses to about 15 pulses, or from 8 pulses to about 10 pulses of each of the first purge gas, the second purge gas, the third purge gas, and/or the fourth purge gas into the processing region during the purge process.

In one or more examples, each of the deposition cycles includes independently introducing from 3 pulses of the purge gas to about 100 pulses of each of the first purge gas, the second purge gas, the third purge gas, and/or the fourth purge gas into the processing region during the purge process. In other examples, each of the deposition cycles includes introducing from 5 pulses of the purge gas to about 50 pulses of each of the first purge gas, the second purge gas, the third purge gas, and/or the fourth purge gas into the processing region during the purge process. In some examples, each of the deposition cycles includes introducing from 8 pulses of the purge gas to about 25 pulses of each of the first purge gas, the second purge gas, the third purge gas, and/or the fourth purge gas into the processing region during the purge process.

In some embodiments, each of the pulses of the purge gas is introduced into the processing region for a period in a range from about 20 seconds, about 30 seconds, about 40 seconds, about 45 seconds, or about 50 seconds to about 60 seconds, about 70 seconds, about 75 seconds, about 80 seconds, about 90 seconds, about 100 seconds, about 120 seconds, or longer during the purge process. For example, the each of the pulses of the purge gas is introduced into the processing region for about 20 seconds to about 120 seconds, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 30 seconds to about 120 seconds, about 30 seconds to about 100 seconds, about 30 seconds to about 90 seconds, about 30 seconds to about 75 seconds, about 30 seconds to about 60 seconds, about 30 seconds to about 45 seconds, about 40 seconds to about 120 seconds, about 40 seconds to about 100 seconds, about 40 seconds to about 90 seconds, about 40 seconds to about 75 seconds, about 40 seconds to about 60 seconds, about 60 seconds to about 120 seconds, about 60 seconds to about 100 seconds, about 60 seconds to about 90 seconds, or about 60 seconds to about 75 seconds during the purge process.

In between the pulses of the purge gas introduced into the processing region is a stagnant period when no purge gas is introduced into the processing region. The purge gas can infiltrate the plurality of powder particles and flush or purge out remnant gases from the particles during the stagnant period. This stagnant period can range from about 20 seconds, about 30 seconds, about 40 seconds, about 45 seconds, or about 50 seconds to about 60 seconds, about 70 seconds, about 75 seconds, about 80 seconds, about 90 seconds, about 100 seconds, about 120 seconds, or longer during the purge process. For example, the stagnant period can last for about 20 seconds to about 120 seconds, about 20 seconds to about 100 seconds, about 20 seconds to about 90 seconds, about 20 seconds to about 75 seconds, about 20 seconds to about 60 seconds, about 20 seconds to about 45 seconds, about 20 seconds to about 30 seconds, about 30 seconds to about 120 seconds, about 30 seconds to about 100 seconds, about 30 seconds to about 90 seconds, about 30 seconds to about 75 seconds, about 30 seconds to about 60 seconds, about 30 seconds to about 45 seconds, about 40 seconds to about 120 seconds, about 40 seconds to about 100 seconds, about 40 seconds to about 90 seconds, about 40 seconds to about 75 seconds, about 40 seconds to about 60 seconds, about 60 seconds to about 120 seconds, about 60 seconds to about 100 seconds, about 60 seconds to about 90 seconds, or about 60 seconds to about 75 seconds.

The cyclic vapor coating process can include a variety of numbers of deposition cycles. In some embodiments, the cyclic vapor coating process can include a number of deposition cycles in a range from 1, 2, 3, 4, 5, 6, 7, or 8 to 9,10, 11, 12, 13, 14, 15, 16, 17, 18, 19, 20, about 22, or about 25 cycles, or more. For example, the cyclic vapor coating process can include a number of deposition cycles from 1 to about 25, from 1 to about 20, from 1 to about 18, from 1 to about 15, from 1 to about 12, from 1 to about 10, from 1 to 9, from 1 to 8, from 1 to 7, from 1 to 6, from 1 to 5, from 1 to 4, from 1 to 3, from 1 to 2, from 2 to about 25, from 2 to about 20, from 2 to about 18, from 2 to about 15, from 2 to about 12, from 2 to about 10, from 2 to 9, from 2 to 8, from 2 to 7, from 2 to 6, from 2 to 5, from 2 to 4, from 2 to 3, from 3 to about 25, from 3 to about 20, from 3 to about 18, from 3 to about 15, from 3 to about 12, from 3 to about 10, from 3 to 9, from 3 to 8, from 3 to 7, from 3 to 6, from 3 to 5, from 3 to 4, from 4 to about 25, from 4 to about 20, from 4 to about 18, from 4 to about 15, from 4 to about 12, from 4 to about 10, from 4 to 9, from 4 to 8, from 4 to 7, from 4 to 6, or from 4 to 5.

In one or more examples, the deposition cycle is repeated from 2 times to about 20 times. In some examples, the deposition cycle is repeated from 3 times to about 10 times. In other examples, the deposition cycle is repeated from 4 times to about 8 times, or from 5 times to about 7 times.

To avoid flow faults, conventional MFC operations are usually performed at high differential pressures (e.g., greater than 10 Torr) between the source ampoule and processing region of the chamber or reactor. To avoid condensation, conventional ampoule vapor delivery via metering valves have precise multi-zone heating, pressure monitoring, and valve timing. The MFC and the stagnation flow during the cyclic vapor coating processes described and discussed in embodiments herein obviates source heating of greater than 25 °C and enables pulse-mode chemical delivery for application-specific particles and vapor coating reactions.

It has been surprising and unexpected that the size or diameter of the orifice for each of the MFC valves is independently selected for enhanced delivery of the respective gas, such as a precursor gas (e.g., metal precursor and oxidizing agent) or a purge gas during the cyclic vapor coating processes 100, 200. Each of the first MFC valve, the second MFC valve, the third MFC valve, the fourth MFC valve, and any other MFC valve described and discussed herein, has a separate orifice for delivering the respective gas, such as a precursor gas (e.g., metal precursor and oxidizing agent) or a purge gas. Each of the orifices has a predetermined size or diameter to assist in providing the desired flow rate for the respective gas. Each of the orifices of the first MFC valve, the second MFC valve, the third MFC valve, the fourth MFC valve, and any other MFC valve described and discussed herein, independently has a diameter in a range from about 0.045 inches, about 0.048 inches, about 0.050 inches, about 0.052 inches, about 0.055 inches, about 0.058 inches, about 0.060 inches, about 0.062 inches, greater than 0.062 inches, about 0.065 inches, about 0.068 inches, about 0.070 inches, about 0.075 inches, or about 0.080 inches to about 0.085 inches, about 0.090 inches, about 0.093 inches, about 0.095 inches, about 0.100 inches, about 0.105 inches, about 0.110 inches, about 0.111 inches, about 0.112 inches, about 0.113 inches, about 0.114 inches, about 0.115 inches, about 0.118 inches, about 0.120 inches, about 0.125 inches, about 0.130 inches, about 0.135 inches, about 0.140 inches, about 0.145 inches, about 0.150 inches, about 0.155 inches, about 0.160 inches, about 0.170 inches, or greater. For example, each of the orifices of the first MFC valve, the second MFC valve, the third MFC valve, the fourth MFC valve, and any other MFC valve described and discussed herein, independently has a diameter of about 0.050 inches to about 0.150 inches, about 0.050 inches to about 0.140 inches, about 0.050 inches to about 0.130 inches, about 0.050 inches to about 0.125 inches, about 0.050 inches to about 0.120 inches, about 0.050 inches to about 0.118 inches, about 0.050 inches to about 0.115 inches, about 0.050 inches to about 0.113 inches, about 0.050 inches to about 0.110 inches, about 0.050 inches to about 0.108 inches, about 0.050 inches to about 0.105 inches, about 0.050 inches to about 0.100 inches, about 0.050 inches to about 0.095 inches, about 0.050 inches to about 0.090 inches, about 0.050 inches to about 0.080 inches, about 0.050 inches to about 0.075 inches, about 0.050 inches to about 0.070 inches, about 0.050 inches to about 0.060 inches, greater than or about 0.062 inches to about 0.150 inches, greater than or about 0.062 inches to about 0.140 inches, greater than or about 0.062 inches to about 0.130 inches, greater than or about 0.062 inches to about 0.125 inches, greater than or about 0.062 inches to about 0.120 inches, greater than or about 0.062 inches to about 0.118 inches, greater than or about 0.062 inches to about 0.115 inches, greater than or about 0.062 inches to about 0.113 inches, greater than or about 0.062 inches to about 0.110 inches, greater than or about 0.062 inches to about 0.108 inches, greater than or about 0.062 inches to about 0.105 inches, greater than or about 0.062 inches to about 0.100 inches, greater than or about 0.062 inches to about 0.095 inches, about 0.062 inches to about 0.093 inches, greater than or about 0.062 inches to about 0.090 inches, greater than or about 0.062 inches to about 0.080 inches, greater than or about 0.062 inches to about 0.075 inches, greater than or about 0.062 inches to about 0.070 inches, greater than or about 0.062 inches to about 0.065 inches, about 0.075 inches to about 0.150 inches, about 0.075 inches to about 0.140 inches, about 0.075 inches to about 0.130 inches, about 0.075 inches to about 0.125 inches, about 0.075 inches to about 0.120 inches, about 0.075 inches to about 0.118 inches, about 0.075 inches to about 0.115 inches, about 0.075 inches to about 0.113 inches, about 0.075 inches to about 0.110 inches, about 0.075 inches to about 0.108 inches, about 0.075 inches to about 0.105 inches, about 0.075 inches to about 0.100 inches, about 0.075 inches to about 0.095 inches, about 0.075 inches to about 0.090 inches, about 0.075 inches to about 0.080 inches, or about 0.075 inches to about 0.078 inches.

In one or more examples, each of the orifices of the first MFC valve, the second MFC valve, the third MFC valve, and the fourth MFC valve independently has a diameter in a range from about 0.050 inches to about 0.150 inches. In some examples, each of the orifices of the first MFC valve, the second MFC valve, the third MFC valve, and the fourth MFC valve independently has a diameter in a range from about 0.062 inches to about 0.113 inches. In other examples, each of the orifices of the first MFC valve, the second MFC valve, the third MFC valve, and the fourth MFC valve independently has a diameter in a range from about 0.075 inches to about 0.105 inches.

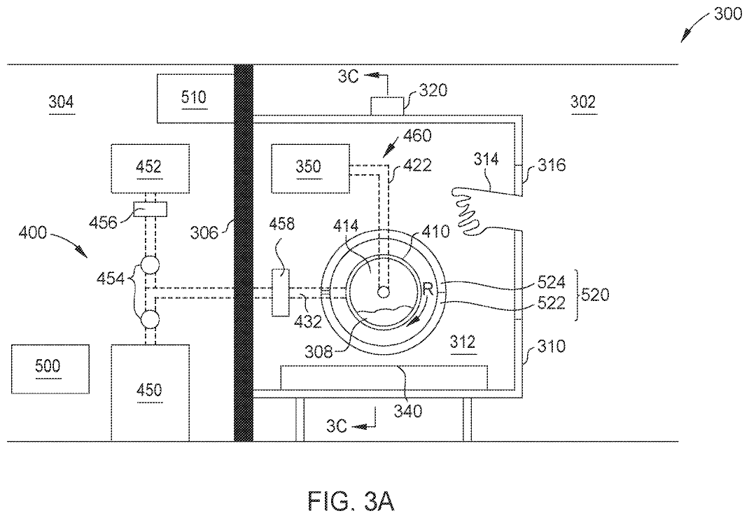

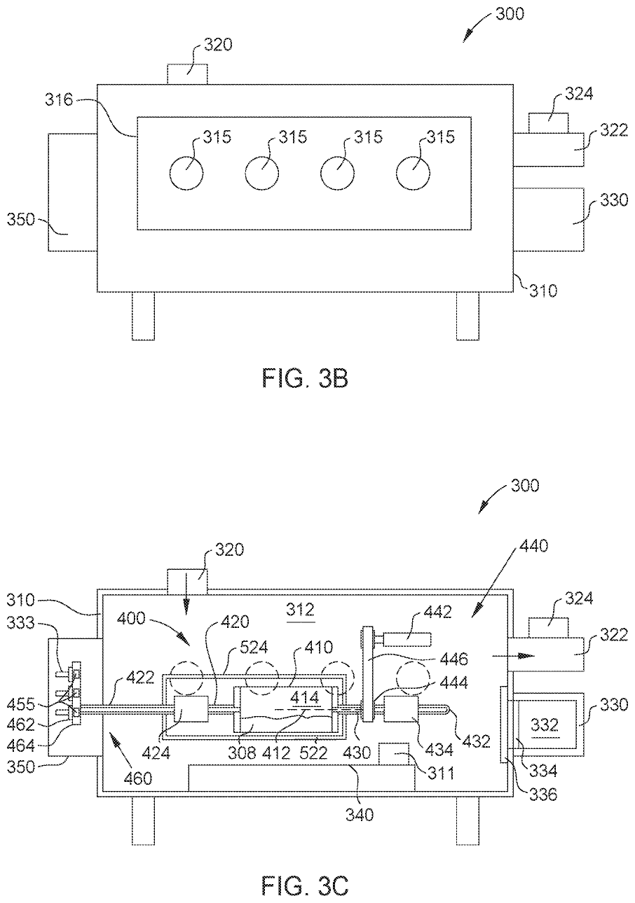

FIGS. 3A-3C illustrate a deposition system 300 for coating particles with a thin-film coating, as described and discussed in one or more embodiments herein. The deposition system 300 can be used to perform cyclic vapor coating processes 100, 200, and other cyclic vapor coating processes, such as a process to coat a plurality of powder particles with a metal oxide coating to form a plurality of coated particles.

FIG. 3A depicts a schematic cross-sectional front view of the deposition system 300 for performing cyclic vapor coating processes to coat particles. The deposition system 300 includes a rotary cylindrical reactor tube 410 (e.g., a rotary vacuum chamber). FIG. 3B depicts a schematic side view of the deposition system 300 shown in FIG. 3A. FIG. 3C is a schematic cross-sectional side view of the deposition system 300 shown in FIG. 3A. The view of FIG. 3C can be taken along line 3C-3C in FIG. 3A.

The deposition system 300 includes reactor system 400 which has a rotary cylindrical reactor tube 410 (also referred to as a “drum”) which can be partially filled with a plurality of powder particles 308 to form a particle bed within the processing region 414 of the reactor drum 410. In brief, as the reactor drum rotates, one or more process gasses are injected into the drum through an inlet port and exhausted from the drum through an outlet port. Thus, the plurality of powder particles 308 in the drum undergo tumbling agitation so that the gasses can be applied uniformly to the particles and deposit a metal oxide layer or coating on the powder particles to produce the coated particles. In one or more examples, the powder particles and/or the coated particles can have an average or median size (PSD D50) of about 0.5 μm to about 200 μm, about 2 μm to about 200 μm, or about 5 μm to about 100 μm.

The deposition system 300 also include an isolator 310 that forms an isolated chamber 312. At least some components of the reactor system, including at least the reactor tube 410, are located in the chamber 312 of the isolator 310. The isolator 310 can be a glovebox that includes one or more, e.g., four, gloves 314 (ports 315 for the gloves are shown in FIG. 3B). A front panel 316 of the isolator 310 can be transparent, e.g., formed of monolithic tempered glass, so that an operator can view the interior chamber of the isolator 310. In addition, the gloves 314 are positioned so that the operator can manipulate parts of the reactor system 400, e.g., to remove a reactor tube 410 containing coated particles after the deposition process from other portions of the reactor system 400, and to install a new reactor tube with uncoated particles for a subsequent deposition process. The isolator 310 can provide ISO 10648-2 Class- 2 containment against leaks and/or containment for APIs up to OEB 5 toxicity levels.

The isolator 310 can include an air intake port 320 with an H14 HEPA filter to filter air entering the interior chamber 312, and an exhaust pump 322 connected to an air outlet port 324, also with an H14 HEPA filter. One or more outlet ports (not shown) may return air to the environment around the isolator 310, or alternatively; the one or more outlet ports could be coupled directly to facility exhaust line for further processing. The exhaust pump operates to bring the interior chamber 312 to about −50 Pa to about −100 Pa relative to the surrounding pressure in the environment around the isolator 310. Additionally, the isolator can be configured for aseptic operation at pressures slightly above atmospheric pressure, e.g., about 2%-20% above atmospheric pressure. In some implementations, a polished hygienic stainless steel filter housing can be used with a USP Class VI 0.2 μm exhaust filter. Additionally or alternatively, an oxidizer ampoule heater can heat water up to 135 °C for sterilization. Sterilization can follow refilling the ampoule, and periodically as needed.

As shown in FIGS. 3B and 3C, the isolator 310 also includes a rapid transfer port. In particular, the rapid transfer port includes a detachable transfer container 330 with an interior space 332. The transfer container can be sealed by a valve 334, and similarly the access port connecting the container 330 to the isolator 310 can be sealed by a valve 336. When both valves 334, 336 are open, the interior space 332 of the container 330 can be accessed by an operator using a glove 314. For example, the reactor drum 410 could be placed into transfer container 330. As another example, coated particles could be transferred inside the isolator 310 from the reactor drum 410 into a canister 311, and then the canister could be placed by the operator (using a glove 314) into the container 330. When both valves 334, 336 are closed, the canister 130 can be manually detached from the isolator so that the contents can be transported to another location, e.g., for removal of coated particles from the drum, or for further processing of the particles such as mixture with excipients, pressing into a tablet, or encapsulation in a shell, without danger of contamination of the coated particles or the interior of the isolator 310.

The interior 312 of the isolator 310 can also include a stand or platform 340 to support various components, e.g., parts of the reactor system 400 or tools used for assembly or disassembly of the reactor system 400 or for transfer of powder, within reach of the operator using a gloves 314. For example, the canister 311 could be placed on the platform 340.

As illustrated in FIG. 3A, some portions of the deposition system 300, e.g., the isolator 310 and the rotatable reactor drum 410, can be located in a cleanroom 302. In contrast, some other portions of the deposition system 300, e.g., a vacuum pump 250 for the reactor system 400 and an electrical cabinet 510 can be located in a technical area 304 at a much lower level of cleanliness than the cleanroom 302. The cleanroom 302 can be separated from the technical area by a partition wall 306. A controller 500, e.g., a programmed general purpose computer, can be located in the technical area 304 for the operator to control operation of the reactor system 400. In some implementations, the user interface for the controller 500 (e.g., a touch screen display, keyboard) is located in the cleanroom 302.

Referring to FIG. 3A, the deposition system 300 also includes a heater assembly 520 to control the temperature of at least the reactor drum 410. The heater assembly 520 can include two half-cylindrical blocks, a lower half-cylindrical block 522 and an upper half-cylindrical block 324. Embedded in or placed on the surface of each cylindrical block 522 are one or more heating elements (e.g., a resistive heater with power supplied from the electrical cabinet 510). Each cylindrical block can be formed of a heat-sink material, e.g., anodized aluminum.

Returning to FIG. 3A, the controller 500 is configured to operate the reactor system 400 in accord with a “recipe”. The recipe specifies an operating value for each controllable element as a function of time. For example, the recipe can specify the times during which the vacuum source 450 is to operate, the times of and flow rate for each gas source, the rotation rate of the rotary reaction drum 410 as set by the motor 442. The controller 500 can receive the recipe as computer-readable data (e.g., that is stored on a non-transitory computer readable medium).

Referring to FIG. 3C, the reactor system 400 will be further described. The reactor system 400 includes the rotatable reactor drum 410, a rotatable inlet tube 420, and a rotatable outlet tube 430. The rotatable inlet tube 420 and the rotatable outlet tube 430 are co-linear with the axis of rotation 412 of the rotatable reactor drum 410. The rotatable inlet tube 420 is fluidly coupled to a stationary inlet line 422 by an inlet rotary seal 424, and the rotatable outlet tube 430 is fluidly coupled to a stationary outlet line 432 by an outlet rotary seal 434. The rotary seals 424, 434 can reduce the risk of escape of particles from the reactor system 400.

For the rotary seals 424, 434, one option would be to use a labyrinth seal. In general, the circuitous path in a labyrinth seal can provide many opportunities for particles to adhere to a seal surface. A labyrinth seal may help maintain vacuum without need of external purge gas.

Another option for the rotary seals 424, 434 is a double cartridge mechanical seal. Such a mechanical seal can include a pair of bearings. In each bearing, an inner ring makes physical contact with an outer ring. Because the rings are in physical contact, the relative motion can result in wear, so the rings can be formed of a non-toxic material that will not interfere with the deposition process, e.g., graphite, or a ceramic with very low wear rate. A purge gas can be injected into the space between the pair of bearings to prevent atmospheric leakage into the reactor. For example, pressure of the purge gas can be controlled from less than 10 m Torr to about 30 psig to avoid N₂ leakage into reactor and to prevent contamination from air.

The rotatable outlet tube 430 can also function as a drive shaft for the rotatable reactor drum 410. In particular, a rotary drive system 440 includes a drive motor 442 to rotate the rotatable components, e.g., reactor drum 410, a rotatable inlet tube 420, and a rotatable outlet tube 430. A drive wheel 444 is fixed to the rotatable outlet tube 430 at a spot between the reactor drum 410 and the outlet rotary seal 434. The drive wheel 444 is coupled to the motor 442 by a drive belt 446. In operation, the rotary drive motor system 440 can rotate the reactor drum 410 at about 1 rpm to about 50 rpm, e.g., about 6 rpm to about 50 rpm. Motion of the reactor drum 410 can be clockwise (CW), counter-clockwise (CCW), or can alternate between CW and CCW.

Returning to FIG. 3A, the deposition system 300 includes a vacuum source 450 (e.g., one or more vacuum pumps) coupled to the outlet line 432. The vacuum source 450 can be an industrial vacuum pump sufficient to establish pressures less than 1 Torr, e.g., about 1 m Torr to about 100 mTorr, e.g., about 20 m Torr to about 100 m Torr. In some implementations, the vacuum pump can establish a pressure less than 760 Torr, but at or greater than 1 Torr, e.g., about 1 Torr to about 100 Torr. The vacuum source 450 permits the interior 414 of the reactor drum 410 to be maintained at a desired pressure, and permits removal of reaction byproducts and unreacted process gases.

In some implementations, a purge gas source 452 is connected to the outlet line 432, e.g., to create a back-pressure to remove powder blockage of the reactor drum end caps discussed below. The purge gas can be, for example, argon or nitrogen. One or more valves 454 can be used to control whether the vacuum source 450 or the purge gas source 452 is coupled to the outlet line 432.

An ultra-low particulate air filter 458 can be plated in outlet line 432 between the vacuum source 450 and the outlet rotary seal 434 to prevent powder contamination downstream of the filter housing. In some implementations, the ultra-low particulate air filter 458 can be a hygienic Parker demi stainless steel filter housing with a 0.2 μm TETPOR Air Filter Cartridge that meets USP Class VI standards. The housing can have additional polishing on the surfaces upstream of the filter to a 0.4 roughness (Ra) surface finish, and O-rings, e.g., USP Class VI Viton O-Rings, can be used for sealing of joints between parts. The upstream surfaces of the ultra-low particulate air filter 458 can be in contact with the API, so having surfaces that can be adequately cleaned can prevent biologic contamination.

A chemical delivery system 460 includes multiple fluid sources coupled by respective delivery tubes and controllable valves to the inlet line 422. The chemical delivery system 460 injects the fluid in a vapor form into the reactor drum 410. The chemical delivery system 460 include a combination of restrictors, gas flow controllers, pressure transducers, and thermal mass flow controllers/meters to provide controllable flow rate of the various gasses into the reactor drum 410. The chemical delivery system 460 can also include one or more temperature control components (e.g., a heat exchanger, resistive heater) to heat or cool the various gasses before they flow into the reactor drum 410.

As shown in FIG. 3C, an ampule cabinet 350 can be located adjacent the isolator 310. The ampule cabinet 350 includes a portion of the chemical delivery system 460 for the reactor system 400. In particular, located in the ampule cabinet 350 are one or more ports 462 configured to receive one or more ampules 333 or other precursor or gas sources containing precursors or purge gas (e.g., gas or liquid form) for the cyclic vapor coating processes described and discussed herein. The ports 4632 can be coupled by a manifold 464 that can include the various delivery tubes and controllable valves to control flow to the inlet line 422. For example, the ampule cabinet 350 can include three or more ports 462 and three or more mass flow control (MFC) valves 455—two MFC valves 455 for two metal precursors (one precursor per valve) and one MFC valve 455 for an oxidizing agent. The reagents and/or process gases can be, for example, a first metal precursor, a second metal precursor, an oxidizing agent, and one or more purge gases. For example, one or more aluminum precursors, one or more zinc precursors, water vapor, and a purge gas containing N₂ and/or argon. Each of the MFC valves 455, 456 can independently contain an orifice having a diameter in a range from about 0.050 inches to about 0.150 inches, about 0.062 inches to about 0.113 inches, or about 0.075 inches to about 0.105 inches.

In some embodiments, the chemical delivery system 460 can include five fluid sources. Two of the fluid sources can provide the two chemically different precursors or reactants for the deposition process for forming a metal oxide coating or layer on the particles. In one or more examples, the first fluid source can provide a first metal source, such as an aluminum precursor (e.g., trimethylaluminum (TMA)), to the first MFC valve 455, the second source can provide a purge gas (e.g., N₂ and/or Ar) to the second MFC valve 455, and the third source can provide an oxidizing agent (e.g., water) to the third MFC valve 455. In some examples, the first fluid source can provide a first metal source, such as a zinc precursor (e.g., diethyl zinc (DEZ)), to the first MFC valve 455, the second source can provide a purge gas (e.g., N₂ and/or Ar) to the second MFC valve 455, and the third source can provide an oxidizing agent (e.g., water) to the third MFC valve 455. In other examples, the first fluid source can provide a first metal precursor, an aluminum precursor (e.g., trimethylaluminum (TMA)), to the first MFC valve 455, the purge gas source 452 can provide a purge gas (e.g., N₂ and/or Ar) to the MFC valve 456, the second source can provide an oxidizing agent (e.g., water) to the second MFC valve 455, and the third source can provide a second metal precursor, such as a zinc precursor (e.g., diethyl zinc (DEZ)), to the third MFC valve 455.

Returning to FIG. 3A, the mass flow of the chemistry to the reactor can sensed by a MFC valve 456, e.g., in the inlet line 432. The MFC valve 456 can send a signal indicating the mass flow rate to the controller 500, and the controller 500 can control the valves based on the received signal to establish a desired mass flow rate, thus providing a mass flow controller.

The MFC valve 456 can be a thermal MFC. Such a thermal MFC senses changes in temperature in order to determine mass flow rate. Different materials have different calibration constants, e.g., different partial pressures as a function of temperature. The calibration constant needs to be programmed into the thermal MFC to properly convert a temperature measurement to a mass flow measurement. However, the calibration constant for TMA has been determined through empirical measurement and been found to be unexpectedly low, e.g., an Antoine vapor pressure ranging from about 9 Torr at about 20 °C to about 16 Torr at about 30 °C, which is about half that of water or DEZ. Due to the unusually low calibration constant, the mass flow controller itself may need to be customized, e.g., for orifice size and flow rate range. This can enable a high flow rate using a low vapor pressure source.

The controller 500 and other computing devices part of systems described herein can be implemented in digital electronic circuitry, or in computer software, firmware, or hardware. For example, the controller can include a processor to execute a computer program as stored in a computer program product, e.g., in a non-transitory machine readable storage medium. Such a computer program (also known as a program, software, software application, or code) can be written in any form of programming language, including compiled or interpreted languages, and it can be deployed in any form, including as a standalone program or as a module, component, subroutine, or other unit suitable for use in a computing environment. In some implementations, the controller 500 is a general purpose programmable computer. In some implementations, the controller can be implemented using special purpose logic circuitry, e.g., an FPGA (field programmable gate array) or an ASIC (application specific integrated circuit).

For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions. The present disclosure provides apparatus for and methods of preparing pharmaceutical compositions comprising API containing particles encapsulated by one or more layers of metal oxide and/or one or more layers of a polymer. The coating layers are conformal and of controlled thickness from several nanometers to several micrometers in total. The articles to be coated can be composed of only API or a combination of API and one or more excipients. The coating process described herein can provide an API with an increased glass transition temperature for the API relative to uncoated API, a decreased rate of crystallization for an amorphous form of the API relative to uncoated API, and decreased surface mobility of API molecules in the particle compared to uncoated API. Importantly, particle dissolution can be altered. Because the coating is relatively thin, drug products with high drug loading can be achieved. Finally, there are benefits with respect to cost and ease of manufacture because multiple coatings can be applied in the same reactor.

In one or more embodiments, a method of forming, producing, or otherwise preparing a coated powder composition is provided and includes positioning a plurality of powder particles within a processing region of a processing chamber, such as the deposition system 300, where each of the powder particles can be or contain an organic material, and coating the plurality of powder particles with a metal oxide coating to form a plurality of coated particles during a cyclic vapor coating process. The metal oxide coating contains aluminum oxide, zinc oxide, or aluminum zinc oxide. The cyclic vapor coating process includes one, two, or more deposition cycles. The controller 500 is configured to and can be used to execute the following deposition cycles for the cyclic vapor coating process. Each of the deposition cycles includes introducing two or more pulses of a metal precursor (aluminum or zinc precursor) into the processing region via a first MFC valve having an orifice with a diameter in a range from about 0.050 inches to about 0.150 inches, or from about 0.062 inches to about 0.113 inches, exposing the plurality of powder particles to the metal precursor, and infiltrating the plurality of powder particles with the metal precursor via spaces between the powder particles. Thereafter, each of the deposition cycles includes introducing two or more pulses of a purge gas (e.g., N₂ or Ar) into the processing region via a second MFC valve having an orifice with a diameter in a range from about 0.050 inches to about 0.150 inches, or from about 0.062 inches to about 0.113 inches, and exposing the plurality of powder particles to the purge gas during a first purge process. Thereafter, each of the deposition cycles includes introducing two or more pulses of an oxidizing agent (e.g., water vapor) into the processing region via a third MFC valve having an orifice with a diameter in a range from about 0.050 inches to about 0.150 inches, or from about 0.062 inches to about 0.113 inches, exposing the plurality of powder particles to the oxidizing agent, and infiltrating the plurality of powder particles with the oxidizing agent via spaces between the powder particles to produce the metal oxide coating disposed on outer surfaces of each of the powder particles. Thereafter, each of the deposition cycles includes introducing two or more pulses of the purge gas via the second MFC valve, and exposing the plurality of powder particles to the purge gas during a second purge process.

In some embodiments, a method of forming, producing, or otherwise preparing a coated powder composition is provided and includes positioning a plurality of powder particles within a processing region of a processing chamber, such as the deposition system 300, where each of the powder particles can be or contain an inorganic material, and coating the plurality of powder particles with a metal oxide coating to form a plurality of coated particles during a cyclic vapor coating process. The metal oxide coating contains aluminum oxide, zinc oxide, or aluminum zinc oxide. The cyclic vapor coating process includes one, two, or more deposition cycles. The controller 500 is configured to and can be used to execute the following deposition cycles for the cyclic vapor coating process. Each of the deposition cycles includes introducing two or more pulses of a metal precursor into the processing region via a first MFC valve having an orifice with a diameter in a range from about 0.050 inches to about 0.150 inches, or from about 0.062 inches to about 0.113 inches, exposing the plurality of powder particles to the metal precursor, and infiltrating the plurality of powder particles with the metal precursor via spaces between the powder particles. Thereafter, each of the deposition cycles includes introducing two or more pulses of a purge gas into the processing region via a second MFC valve having an orifice with a diameter in a range from about 0.050 inches to about 0.150 inches, or from about 0.062 inches to about 0.113 inches, and exposing the plurality of powder particles to the purge gas during a first purge process. Thereafter, each of the deposition cycles includes introducing two or more pulses of an oxidizing agent into the processing region via a third MFC valve having an orifice with a diameter in a range from about 0.050 inches to about 0.150 inches, or from about 0.062 inches to about 0.113 inches, exposing the plurality of powder particles to the oxidizing agent, and infiltrating the plurality of powder particles with the oxidizing agent via spaces between the powder particles to produce the metal oxide coating disposed on outer surfaces of each of the powder particles. Thereafter, each of the deposition cycles includes introducing two or more pulses of the purge gas via the second MFC valve, and exposing the plurality of powder particles to the purge gas during a second purge process.

In other embodiments, a method of forming, producing, or otherwise preparing a coated powder composition is provided and includes positioning a plurality of powder particles within a processing region of a processing chamber, such as the deposition system 300, and coating the plurality of powder particles with a metal oxide coating to form a plurality of coated particles during a cyclic vapor coating process. The metal oxide coating contains aluminum zinc oxide. The cyclic vapor coating process includes one, two, or more deposition cycles. The controller 500 is configured to and can be used to execute the following deposition cycles for the cyclic vapor coating process. Each of the deposition cycles includes introducing two or more pulses of a first metal precursor (e.g., aluminum precursor) into the processing region via a first MFC valve having an orifice with a diameter in a range from about 0.050 inches to about 0.150 inches, or from about 0.062 inches to about 0.113 inches, exposing the plurality of powder particles to the first metal precursor, and infiltrating the plurality of powder particles with the first metal precursor via spaces between the powder particles. Thereafter, each of the deposition cycles includes introducing two or more pulses of a purge gas (e.g., N₂ or Ar) into the processing region via a second MFC valve having an orifice with a diameter in a range from about 0.050 inches to about 0.150 inches, or from about 0.062 inches to about 0.113 inches, and exposing the plurality of powder particles to the purge gas during a first purge process. Thereafter, each of the deposition cycles includes introducing two or more pulses of an oxidizing agent (e.g., water vapor) into the processing region via a third MFC valve having an orifice with a diameter in a range from about 0.050 inches to about 0.150 inches, or from about 0.062 inches to about 0.113 inches, exposing the plurality of powder particles to the oxidizing agent, and infiltrating the plurality of powder particles with the oxidizing agent via spaces between the powder particles to produce a first metal oxide layer disposed on outer surfaces of each of the powder particles. Thereafter, each of the deposition cycles includes introducing two or more pulses of the purge gas via the second MFC valve, and exposing the plurality of powder particles to the purge gas during a second purge process. Thereafter, each of the deposition cycles includes introducing two or more pulses of a second metal precursor (e.g., zinc precursor) into the processing region via a fourth MFC valve having an orifice with a diameter in a range from about 0.050 inches to about 0.150 inches, or from about 0.062 inches to about 0.113 inches, exposing the plurality of powder particles to the second metal precursor, and infiltrating the plurality of powder particles with the second metal precursor via spaces between the powder particles. Thereafter, each of the deposition cycles includes introducing two or more pulses of the purge gas into the processing region via the second MFC valve, and exposing the plurality of powder particles to the purge gas during a third purge process. Thereafter, each of the deposition cycles includes introducing two or more pulses of the oxidizing agent into the processing region via the third MFC valve, exposing the plurality of powder particles to the oxidizing agent, and infiltrating the plurality of powder particles with the oxidizing agent via spaces between the powder particles to produce a second metal oxide layer disposed on the first metal oxide layer disposed on the outer surfaces of each of the powder particles. Thereafter, each of the deposition cycles includes introducing two or more pulses of the purge gas via the second MFC valve, and exposing the plurality of powder particles to the purge gas during a fourth purge process. The first and second metal precursors are different from each other. The metal oxide coating contains the first metal oxide layer and the second metal oxide layer. The first metal oxide layer contains aluminum oxide, then the second metal oxide layer contains zinc oxide, or alternatively, the first metal oxide layer contains zinc oxide, then the second metal oxide layer contains aluminum oxide.

### Coated Particles Product

The coated powder compositions are produced, fabricated, or otherwise prepared by the cyclic vapor coating processes 100, 200. Each of the coated particles of the coated powder composition has a core containing a powder particle and a metal oxide coating. The powder particle can be or include one or more organic materials or compounds, one or more inorganic materials or compounds, or any combination thereof. In some examples, the powder particle comprises, consists, or consists essential of one or more organic materials or compounds, one or more inorganic materials or compounds, or any combination thereof. The metal oxide coating can be or include one or more aluminum oxide, zinc oxide, or aluminum zinc oxide. In some examples, the metal oxide coating comprises, consists, or consists essential of aluminum oxide, zinc oxide, or aluminum zinc oxide.

The plurality of coated particles can have an average particle size in a range from about 0.1 μm, about 0.2 μm, about 0.3 μm, about 0.5 μm, about 0.8 μm, about 1 μm, about 2 μm, about 3 μm, about 5 μm, about 8 μm, about 10 μm, about 12 μm, about 15 μm, about 18 μm, about 20 μm, about 25 μm, about 30 μm, or about 35 μm to about 40 μm, about 50 μm, about 60 μm, about 70 μm, about 80 μm, about 90 μm, about 100 μm, about 120 μm, about 150 μm, about 200 μm, about 300 μm, about 400 μm, about 500 μm, about 600 μm, about 700 μm, about 800 μm, about 900 μm, or about 1,000 μm. For example, the plurality of coated particles can have an average particle size of about 0.1 μm to about 1,000 μm, about 0.1 μm to about 500 μm, about 0.1 μm to about 200 μm, about 0.1 μm to about 150 μm, about 0.1 μm to about 100 μm, about 0.1 μm to about 80 μm, about 0.1 μm to about 50 μm, about 0.1 μm to about 30 μm, about 0.1 μm to about 20 μm, about 0.1 μm to about 10 μm, about 0.1 μm to about 8 μm, about 0.1 μm to about 5 μm, about 0.1 μm to about 2 μm, about 0.1 μm to about 1 μm, about 0.1 μm to about 0.5 μm, about 1 μm to about 1,000 μm, about 1 μm to about 500 μm, about 1 μm to about 200 μm, about 1 μm to about 150 μm, about 1 μm to about 100 μm, about 1 μm to about 80 μm, about 1 μm to about 50 μm, about 1 μm to about 30 μm, about 1 μm to about 20 μm, about 1 μm to about 10 μm, about 1 μm to about 8 μm, about 1 μm to about 5 μm, about 1 μm to about 2 μm, about 10 μm to about 1,000 μm, about 10 μm to about 500 μm, about 10 μm to about 200 μm, about 10 μm to about 150 μm, about 10 μm to about 100 μm, about 10 μm to about 80 μm, about 10 μm to about 50 μm, about 10 μm to about 30 μm, about 10 μm to about 20 μm, or about 10 μm to about 15 μm.

In one or more examples, the plurality of coated particles can have an average particle size of about 1 μm to about 1,000 μm. In some examples, the plurality of coated particles can have an average particle size of about 1 μm to about 100 μm. In other examples, the plurality of coated particles can have an average particle size of about 1 μm to about 30 μm, or about 1 μm to about 10 μm.

The metal oxide coating of each of the coated particles can have a thickness in a range from about 0.5 nm, about 1 nm, about 2 nm, about 3 nm, about 5 nm, about 8 nm, about 10 nm, about 12 nm, about 15 nm, about 18 nm, about 20 nm, about 25 nm, about 30 nm, or about 35 nm to about 40 nm, about 50 nm, about 60 nm, about 70 nm, about 80 nm, about 90 nm, about 100 nm, about 150 nm, about 200 nm, or greater. For example, the metal oxide coating has a thickness of about 0.5 to about 200 nm, about 1 nm to about 100 nm, about 1 nm to about 95 nm, about 1 nm to about 90 nm, about 1 nm to about 80 nm, about 1 nm to about 70 nm, about 1 nm to about 50 nm, about 1 nm to about 40 nm, about 1 nm to about 30 nm, about 1 nm to about 25 nm, about 1 nm to about 20 nm, about 1 nm to about 15 nm, about 1 nm to about 10 nm, about 1 nm to about 5 nm, about 1 nm to about 3 nm, about 10 nm to about 100 nm, about 10 nm to about 95 nm, about 10 nm to about 90 nm, about 10 nm to about 80 nm, about 10 nm to about 70 nm, about 10 nm to about 50 nm, about 10 nm to about 40 nm, about 10 nm to about 30 nm, about 10 nm to about 25 nm, about 10 nm to about 20 nm, about 10 nm to about 15 nm, about 20 nm to about 100 nm, about 20 nm to about 95 nm, about 20 nm to about 90 nm, about 20 nm to about 80 nm, about 20 nm to about 70 nm, about 20 nm to about 50 nm, about 20 nm to about 40 nm, about 20 nm to about 30 nm, or about 20 nm to about 25 nm.

In one or more examples, the metal oxide coating of each of the coated particles has a thickness of about 0.5 nm to about 200 nm. In some examples, the metal oxide coating has a thickness of about 1 nm to about 100 nm. In other examples, the metal oxide coating has a thickness of about 10 nm to about 50 nm.

In one or more embodiments, the cyclic vapor coating process described and discussed herein provides low thermal budget and condensation free metal organic vapor flow; stable and reproducible mass flow on increasing chamber backpressure; accurate chemical consumption per pulse or per process run; reproducible chemical concentration treatments at low vapor pressures with other reactive chemical sources or oxidizers; and reproducible process to process chemical concentration control and mass flow verification.

High surface area substrates such as API and other powder particles can be coated with metal oxide coatings to impart various bulk and particle-scale properties including but not limited to improved flowability and dissolution rates. Vapor phase metal oxide coating high surface area substrates is not trivial: vapor diffusion inhibition due to chamber geometry, variation in vapor species molecular sticking coefficients, variation in substrate surface morphology and functional groups, and total chamber pressure variation during processing can increase or decrease vapor condensation and chemical bonding on high surface area substrates at low pressure (<20 Torr) and low temperature (<25 °C). Embodiments described and discussed herein provide methods to reproducibly deliver metal organic vapor to a processing chamber.

Embodiments of the present disclosure further relate to any one or more of the following Examples 1-31:
1. A method of forming a coated powder composition, comprising: positioning a plurality of powder particles within a processing region of a processing chamber, wherein each of the powder particles comprises an organic material; and coating the plurality of powder particles with a metal oxide coating to form a plurality of coated particles during a cyclic vapor coating process, wherein the metal oxide coating comprises aluminum oxide, zinc oxide, or aluminum zinc oxide, and wherein the cyclic vapor coating process comprises one or more deposition cycles, and each of the deposition cycles comprises: introducing two or more pulses of a metal precursor into the processing region via a first mass flow control valve; exposing the plurality of powder particles to the metal precursor; infiltrating the plurality of powder particles with the metal precursor via spaces between the powder particles; then introducing two or more pulses of a purge gas into the processing region via a second mass flow control valve; exposing the plurality of powder particles to the purge gas during a first purge process; then introducing two or more pulses of an oxidizing agent into the processing region via a third mass flow control valve; exposing the plurality of powder particles to the oxidizing agent; infiltrating the plurality of powder particles with the oxidizing agent via spaces between the powder particles to produce the metal oxide coating disposed on outer surfaces of each of the powder particles; then introducing two or more pulses of the purge gas via the second mass flow control valve; and exposing the plurality of powder particles to the purge gas during a second purge process.
2. A method of forming a coated powder composition, comprising: positioning a plurality of powder particles within a processing region of a processing chamber, wherein each of the powder particles comprises an inorganic material; and coating the plurality of powder particles with a metal oxide coating to form a plurality of coated particles during a cyclic vapor coating process, wherein the metal oxide coating comprises aluminum oxide, zinc oxide, or aluminum zinc oxide, and wherein the cyclic vapor coating process comprises one or more deposition cycles, and each of the deposition cycles comprises: introducing two or more pulses of a metal precursor into the processing region via a first mass flow control valve; exposing the plurality of powder particles to the metal precursor; infiltrating the plurality of powder particles with the metal precursor via spaces between the powder particles; then introducing two or more pulses of a purge gas into the processing region via a second mass flow control valve; exposing the plurality of powder particles to the purge gas during a first purge process; then introducing two or more pulses of an oxidizing agent into the processing region via a third mass flow control valve; exposing the plurality of powder particles to the oxidizing agent; infiltrating the plurality of powder particles with the oxidizing agent via spaces between the powder particles to produce the metal oxide coating disposed on outer surfaces of each of the powder particles; then introducing two or more pulses of the purge gas via the second mass flow control valve; and exposing the plurality of powder particles to the purge gas during a second purge process.
3. A method of forming a coated powder composition, comprising: positioning a plurality of powder particles within a processing region of a processing chamber; and coating the plurality of powder particles with a metal oxide coating to form a plurality of coated particles during a cyclic vapor coating process, wherein the metal oxide coating comprises aluminum zinc oxide, and wherein the cyclic vapor coating process comprises one or more deposition cycles, and each of the deposition cycles comprises: introducing two or more pulses of a first metal precursor into the processing region via a first mass flow control valve; exposing the plurality of powder particles to the first metal precursor; infiltrating the plurality of powder particles with the first metal precursor via spaces between the powder particles; then introducing two or more pulses of a purge gas into the processing region via a second mass flow control valve; exposing the plurality of powder particles to the purge gas during a first purge process; then introducing two or more pulses of an oxidizing agent into the processing region via a third mass flow control valve; exposing the plurality of powder particles to the oxidizing agent; infiltrating the plurality of powder particles with the oxidizing agent via spaces between the powder particles to produce a first metal oxide layer disposed on outer surfaces of each of the powder particles; then introducing two or more pulses of the purge gas via the second mass flow control valve; exposing the plurality of powder particles to the purge gas during a second purge process; introducing two or more pulses of a second metal precursor into the processing region via a fourth mass flow control valve; exposing the plurality of powder particles to the second metal precursor; infiltrating the plurality of powder particles with the second metal precursor via spaces between the powder particles; then introducing two or more pulses of the purge gas into the processing region via the second mass flow control valve; exposing the plurality of powder particles to the purge gas during a third purge process; then introducing two or more pulses of the oxidizing agent into the processing region via the third mass flow control valve; exposing the plurality of powder particles to the oxidizing agent; infiltrating the plurality of powder particles with the oxidizing agent via spaces between the powder particles to produce a second metal oxide layer disposed on the first metal oxide layer disposed on the outer surfaces of each of the powder particles; then introducing two or more pulses of the purge gas via the second mass flow control valve; and exposing the plurality of powder particles to the purge gas during a fourth purge process; wherein the first and second metal precursors are different from each other; wherein the metal oxide coating comprises the first metal oxide layer and the second metal oxide layer; and wherein the first metal oxide layer comprises aluminum oxide, then the second metal oxide layer comprises zinc oxide, or alternatively, the first metal oxide layer comprises zinc oxide, then the second metal oxide layer comprises aluminum oxide.
4. The method according to example 3, wherein the first or second metal precursor comprises trimethyl aluminum, dimethyl aluminum hydride, triethyl aluminum, diethyl aluminum hydride, tripropyl aluminum, dipropyl aluminum hydride, tributyl aluminum, dibutyl aluminum hydride, isomers thereof, salts thereof, of any combination thereof.
5. The method according to example 3 or 4, wherein the first or second metal precursor comprises dimethyl zinc, diethyl zinc, dipropyl zinc, dibutyl zinc, isomers thereof, salts thereof, of any combination thereof.
6. The method according to any one of examples 1-5, wherein each of the powder particles comprises an organic material.
7. The method according to any one of examples 1-6, wherein each of the powder particles comprises an inorganic material.
8. The method according to any one of examples 1-7, wherein each of the pulses of the metal precursor is introduced into the processing region for about 30 seconds to about 60 seconds, each of the pulses of the oxidizing agent is introduced into the processing region for about 30 seconds to about 60 seconds, and each of the pulses of the purge gas is introduced into the processing region for about 30 seconds to about 60 seconds.
9. The method according to any one of examples 1-8, wherein each of the deposition cycles comprises introducing from 3 pulses of the metal precursor to about 100 pulses of the metal precursor into the processing region; or wherein each of the deposition cycles comprises introducing from 5 pulses of the metal precursor to about 50 pulses of the metal precursor; or wherein each of the deposition cycles comprises introducing from 8 pulses of the metal precursor to about 35 pulses of the metal precursor.
10. The method according to any one of examples 1-9, wherein each of the deposition cycles comprises introducing from 3 pulses of the oxidizing agent to about 100 pulses of the oxidizing agent into the processing region; or wherein each of the deposition cycles comprises introducing from 5 pulses of the oxidizing agent to about 50 pulses of the oxidizing agent; or wherein each of the deposition cycles comprises introducing 8 pulses of the oxidizing agent to about 35 pulses of the oxidizing agent.
11. The method according to any one of examples 1-10, wherein each of the deposition cycles comprises introducing from 3 pulses of the purge gas to about 100 pulses of the purge gas into the processing region for each of the first and second purge processes; or wherein each of the deposition cycles comprises introducing from 5 pulses of the purge gas to about 50 pulses of the purge gas into the processing region for each of the first and second purge processes; or wherein each of the deposition cycles comprises introducing from 8 pulses of the purge gas to about 35 pulses of the purge gas into the processing region for each of the first and second purge processes.
12. The method according to any one of examples 1-11, wherein the deposition cycle is repeated from 2 times to about 20 times; or wherein the deposition cycle is repeated from 3 times to about 10 times; or wherein the deposition cycle is repeated from 4 times to about 8 times; or wherein the deposition cycle is repeated from 5 times to about 7 times.
13. The method according to any one of examples 1-12, wherein each of the metal precursor and the oxidizing agent is independently at a partial pressure of less than 2 Torr when being introduced into the processing region.
14. The method according to any one of examples 1-13, wherein each of the metal precursor and the oxidizing agent is independently introduced into the processing region having a stagnate atmosphere at a pressure of less than 760 Torr; or at a pressure from about 10 Torr to about 750 Torr.
15. The method according to any one of examples 1-14, wherein each of the orifices of the first, second, third, and fourth mass flow control valves independently has a diameter in a range from about 0.050 inches to about 0.150 inches, about or greater than 0.062 inches to about 0.113 inches, or about or greater than 0.062 inches to about 0.093 inches.
16. The method according to any one of examples 1-15, wherein the plurality of powder particles are maintained at a temperature in a range from about 15 °C to about 25 °C during the cyclic vapor coating process.
17. The method according to any one of examples 1-16, wherein the metal oxide coating consists essential of aluminum oxide, zinc oxide, or aluminum zinc oxide.
18. The method according to any one of examples 1-17, wherein the metal precursor comprises trimethyl aluminum, dimethyl aluminum hydride, triethyl aluminum, diethyl aluminum hydride, tripropyl aluminum, dipropyl aluminum hydride, tributyl aluminum, dibutyl aluminum hydride, isomers thereof, salts thereof, of any combination thereof.
19. The method according to any one of examples 1-18, wherein the metal precursor comprises dimethyl zinc, diethyl zinc, dipropyl zinc, dibutyl zinc, isomers thereof, salts thereof, of any combination thereof.
20. The method according to any one of examples 1-19, wherein the metal precursor is at a temperature of about −20 °C to about 25 °C, about −20 °C to about 23 °C, about −20 °C to about 20 °C, about −20 °C to about 18 °C, about 0 °C to about 25 °C, about 0 °C to about 23 °C, about 0 °C to about 20 °C, or about 0 °C to about 18 °C and at a pressure of about 0.01 Torr to about 20 Torr when being introduced into the first mass flow control valve.
21. The method according to any one of examples 1-20, wherein the oxidizing agent comprises water, oxygen (O₂), hydrogen peroxide, inorganic peroxide, ozone, atomic oxygen, oxygen plasma, or any combination thereof.
22. The method according to any one of examples 1-21, wherein the purge gas comprises argon, helium, nitrogen (N₂), or any combination thereof.
23. The method according to any one of examples 1-22, wherein the organic material contained in the powder particles comprises one or more active pharmaceutical ingredients (APIs), one or more pharmaceutically acceptable excipients (PAEs), or any combination thereof.
24. The method according to any one of examples 1-23, wherein the inorganic material contained in the powder particles comprises aluminum oxide, titanium dioxide, iron oxide, gallium oxide, magnesium oxide, zinc oxide, niobium oxide, hafnium oxide, tantalum oxide, lanthanum oxide, zirconium dioxide, silicon oxide, silicates thereof, nitrides thereof, or any combination thereof.
25. The method according to any one of examples 1-24, wherein the plurality of powder particles are produced from a spray dried process or a lyophilization process.
26. The method according to any one of examples 1-25, wherein the plurality of powder particles has an average particle size of about 0.1 μm to about 1,000 μm; or about 1 μm to about 100 μm; or about 1 μm to about 30 μm; or about 1 μm to about 10 μm.
27. The method according to any one of examples 1-26, wherein the metal oxide coating has a thickness of about 1 nm to about 100 nm.
28. A method of forming a coated powder composition, comprising: positioning a plurality of powder particles within a processing region of a processing chamber, wherein each of the powder particles comprises active pharmaceutical ingredients (APIs); and coating the plurality of powder particles with a metal oxide coating to form a plurality of coated particles during a cyclic vapor coating process, wherein the metal oxide coating comprises aluminum oxide or zinc oxide, and wherein the cyclic vapor coating process comprises one or more deposition cycles, and each of the deposition cycles comprises: introducing a pulse of a metal precursor into the processing region via a first mass flow control valve having an orifice with a diameter greater than 0.062 inches to about 0.113 inches; exposing the plurality of powder particles to the metal precursor; infiltrating the plurality of powder particles with the metal precursor via spaces between the powder particles; then introducing a pulse of a purge gas into the processing region via a second mass flow control valve; exposing the plurality of powder particles to the purge gas during a first purge process; then introducing a pulse of an oxidizing agent into the processing region via a third mass flow control valve; exposing the plurality of powder particles to the oxidizing agent; infiltrating the plurality of powder particles with the oxidizing agent via spaces between the powder particles to produce the metal oxide coating disposed on outer surfaces of each of the powder particles; then introducing a pulse of the purge gas via the second mass flow control valve; and exposing the plurality of powder particles to the purge gas during a second purge process.
29. A method of forming a coated powder composition, comprising: positioning a plurality of powder particles within a processing region of a processing chamber, wherein each of the powder particles comprises active pharmaceutical ingredients (APIs), wherein the plurality of powder particles are maintained at a temperature in a range from about 15 °C to about 25 °C during the cyclic vapor coating process; and coating the plurality of powder particles with a metal oxide coating to form a plurality of coated particles during a cyclic vapor coating process, wherein the metal oxide coating comprises aluminum oxide, and wherein the cyclic vapor coating process comprises one or more deposition cycles, and each of the deposition cycles comprises: introducing a pulse of a metal precursor into the processing region via a first mass flow control valve having an orifice with a diameter greater than 0.062 inches to about 0.113 inches, wherein the metal precursor is at a temperature of about −20 °C to about 20 °C and at a pressure of about 0.01 Torr to about 20 Torr when being introduced into the first mass flow control valve; exposing the plurality of powder particles to the metal precursor; infiltrating the plurality of powder particles with the metal precursor via spaces between the powder particles; then introducing a pulse of a purge gas into the processing region via a second mass flow control valve; exposing the plurality of powder particles to the purge gas during a first purge process; then introducing a pulse of an oxidizing agent into the processing region via a third mass flow control valve; exposing the plurality of powder particles to the oxidizing agent; infiltrating the plurality of powder particles with the oxidizing agent via spaces between the powder particles to produce the metal oxide coating disposed on outer surfaces of each of the powder particles; then introducing a pulse of the purge gas via the second mass flow control valve; and exposing the plurality of powder particles to the purge gas during a second purge process.
30. The method according to example 28 or 29, further comprising any of the methods described in any one of examples 1-27.
31. A coated powder composition made, produced, fabricated, made, or formed by the method according to any one of examples 1-30.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A method of forming a coated powder composition, comprising:
positioning a plurality of powder particles within a processing region of a processing chamber, wherein each of the powder particles comprises an organic material; and
coating the plurality of powder particles with a metal oxide coating to form a plurality of coated particles during a cyclic vapor coating process, wherein the metal oxide coating comprises aluminum oxide, zinc oxide, or aluminum zinc oxide, and wherein the cyclic vapor coating process comprises one or more deposition cycles, and each of the deposition cycles comprises:
introducing a pulse of a metal precursor into the processing region via a first mass flow control valve;
exposing the plurality of powder particles to the metal precursor;
infiltrating the plurality of powder particles with the metal precursor via spaces between the powder particles; then
introducing two or more pulses of a purge gas into the processing region via a second mass flow control valve;
exposing the plurality of powder particles to the purge gas during a first purge process; then
introducing two or more pulses of an oxidizing agent into the processing region via a third mass flow control valve;
exposing the plurality of powder particles to the oxidizing agent;
infiltrating the plurality of powder particles with the oxidizing agent via spaces between the powder particles to produce the metal oxide coating disposed on outer surfaces of each of the powder particles; then
introducing two or more pulses of the purge gas via the second mass flow control valve; and
exposing the plurality of powder particles to the purge gas during a second purge process.

2. (canceled)

3. The method of claim 1, wherein each of the pulses of the metal precursor is introduced into the processing region for about 30 seconds to about 60 seconds, each of the pulses of the oxidizing agent is introduced into the processing region for about 30 seconds to about 60 seconds, and each of the pulses of the purge gas is introduced into the processing region for about 30 seconds to about 60 seconds.

4. The method of claim 1, wherein each of the deposition cycles comprises introducing from 3 pulses of the metal precursor to about 100 pulses of the metal precursor into the processing region, wherein each of the deposition cycles comprises introducing from 3 pulses of the oxidizing agent to about 100 pulses of the oxidizing agent into the processing region, and wherein each of the deposition cycles comprises introducing from 3 pulses of the purge gas to about 100 pulses of the purge gas into the processing region for each of the first and second purge processes.

5. The method of claim 1, wherein the deposition cycle is repeated from 2 times to about 20 times.

6. The method of claim 1, wherein each of the metal precursor and the oxidizing agent is independently introduced into the processing region having a stagnate atmosphere at a pressure of less than 760 Torr, and wherein each of the first, second, and third mass flow control valves independently contains an orifice with a diameter having in a range from about 0.062 inches to about 0.113 inches.

7. The method of claim 1, wherein each of the first, second, and third mass flow control valves independently contains an orifice with a diameter having in a range from about 0.050 inches to about 0.150 inches.

8. The method of claim 1, wherein the plurality of powder particles are maintained at a temperature in a range from about 15 °C to about 25 °C during the cyclic vapor coating process.

9. The method of claim 1, wherein the metal oxide coating consists essential of aluminum oxide, zinc oxide, or aluminum zinc oxide.

10. The method of claim 1, wherein the metal precursor comprises trimethyl aluminum, dimethyl aluminum hydride, triethyl aluminum, diethyl aluminum hydride, tripropyl aluminum, dipropyl aluminum hydride, tributyl aluminum, dibutyl aluminum hydride, isomers thereof, salts thereof, of any combination thereof.

11. The method of claim wherein the metal precursor comprises dimethyl zinc, diethyl zinc, dipropyl zinc, dibutyl zinc, isomers thereof, salts thereof, of any combination thereof.

12. The method of claim 1, wherein the metal precursor is at a temperature of about −20 °C to about 20 °C and at a pressure of about 0.01 Torr to about 20 Torr when being introduced into the first mass flow control valve.

13. The method of claim wherein the oxidizing agent comprises water, oxygen (O₂), hydrogen peroxide, inorganic peroxide, ozone, atomic oxygen, oxygen plasma, or any combination thereof, and wherein the purge gas comprises argon, helium, nitrogen (N₂), or any combination thereof.

14. The method of claim 1, wherein the organic material contained in the powder particles comprises one or more active pharmaceutical ingredients (APIs), one or more pharmaceutically acceptable excipients (PAEs), or any combination thereof.

15. The method of claim 1, wherein the plurality of powder particles has an average particle size of about 0.1 μm to about 1,000 μm, and wherein the metal oxide coating has a thickness of about 1 nm to about 100 nm.

16. A method of forming a coated powder composition, comprising:
positioning a plurality of powder particles within a processing region of a processing chamber; and
coating the plurality of powder particles with a metal oxide coating to form a plurality of coated particles during a cyclic vapor coating process, wherein the metal oxide coating comprises aluminum oxide, and wherein the cyclic vapor coating process comprises one or more deposition cycles, and each of the deposition cycles comprises:
introducing two or more pulses of a first metal precursor into the processing region via a first mass flow control valve;
exposing the plurality of powder particles to the first metal precursor;
infiltrating the plurality of powder particles with the first metal precursor via spaces between the powder particles; then
introducing two or more pulses of a purge gas into the processing region via a second mass flow control valve;
exposing the plurality of powder particles to the purge gas during a first purge process; then
introducing two or more pulses of an oxidizing agent into the processing region via a third mass flow control valve;
exposing the plurality of powder particles to the oxidizing agent;
infiltrating the plurality of powder particles with the oxidizing agent via spaces between the powder particles to produce a first metal oxide layer disposed on outer surfaces of each of the powder particles; then
introducing two or more pulses of the purge gas via the second mass flow control valve;
exposing the plurality of powder particles to the purge gas during a second purge process;
introducing two or more pulses of a second metal precursor into the processing region via a fourth mass flow control valve;
exposing the plurality of powder particles to the second metal precursor;
infiltrating the plurality of powder particles with the second metal precursor via spaces between the powder particles; then
introducing two or more pulses of the purge gas into the processing region via the second mass flow control valve;
exposing the plurality of powder particles to the purge gas during a third purge process; then
introducing two or more pulses of the oxidizing agent into the processing region via the third mass flow control valve;
exposing the plurality of powder particles to the oxidizing agent;
infiltrating the plurality of powder particles with the oxidizing agent via spaces between the powder particles to produce a second metal oxide layer disposed on the first metal oxide layer disposed on the outer surfaces of each of the powder particles; then
introducing two or more pulses of the purge gas via the second mass flow control valve; and
exposing the plurality of powder particles to the purge gas during a fourth purge process;
wherein the first and second metal precursors are different from each other;
wherein the metal oxide coating comprises the first metal oxide layer and the second metal oxide layer; and
wherein the first metal oxide layer comprises aluminum oxide, then the second metal oxide layer comprises zinc oxide, or alternatively, the first metal oxide layer comprises zinc oxide, then the second metal oxide layer comprises aluminum oxide.

17. The method of claim 16, wherein the deposition cycle is repeated from 2 times to about 20 times.

18. The method of claim 17, wherein each of the first, second, third, and fourth mass flow control valves independently contains an orifice with a diameter having in a range from about 0.062 inches to about 0.113 inches.

19. The method of claim 16, wherein each of the powder particles comprises an organic material.

20. The method of claim 16, wherein each of the powder particles comprises an inorganic material.

21. A method of forming a coated powder composition, comprising:
positioning a plurality of powder particles within a processing region of a processing chamber, wherein each of the powder particles comprises an inorganic material; and
coating the plurality of powder particles with a metal oxide coating to form a plurality of coated particles during a cyclic vapor coating process, wherein the metal oxide coating comprises aluminum oxide, zinc oxide, or aluminum zinc oxide, and wherein the cyclic vapor coating process comprises one or more deposition cycles, and each of the deposition cycles comprises:
introducing two or more pulses of a metal precursor into the processing region via a first mass flow control valve;
exposing the plurality of powder particles to the metal precursor;
infiltrating the plurality of powder particles with the metal precursor via spaces between the powder particles; then
introducing two or more pulses of a purge gas into the processing region via a second mass flow control valve;
exposing the plurality of powder particles to the purge gas during a first purge process; then
introducing two or more pulses of an oxidizing agent into the processing region via a third mass flow control valve;
exposing the plurality of powder particles to the oxidizing agent;
infiltrating the plurality of powder particles with the oxidizing agent via spaces between the powder particles to produce the metal oxide coating disposed on outer surfaces of each of the powder particles; then
introducing two or more pulses of the purge gas via the second mass flow control valve; and
exposing the plurality of powder particles to the purge gas during a second purge process.

22. The method of claim 21, wherein the inorganic material contained in the powder particles comprises aluminum oxide, titanium dioxide, iron oxide, gallium oxide, magnesium oxide, zinc oxide, niobium oxide, hafnium oxide, tantalum oxide, lanthanum oxide, zirconium dioxide, silicon oxide, silicates thereof, nitrides thereof, or any combination thereof.
